(19) United States
(12) Patent Application Publication
(10) Pub. No.: US 2024/0258766 A1
(43) Pub. Date: Aug. 1, 2024

(54) ISOLATION USED FOR INTEGRATED OPTICAL SINGLE MODE LASERS

(71) Applicant: Freedom Photonics LLC, Goleta, CA (US)

(72) Inventor: Gordon Barbour Morrison, Summerland, CA (US)

(21) Appl. No.: 18/421,386

(22) Filed: Jan. 24, 2024

Related U.S. Application Data
(60) Provisional application No. 63/481,533, filed on Jan. 25, 2023.

(51) Int. Cl. H01S 5/024; H01S 5/026; H01S 5/125

(52) U.S. Cl. CPC H01S 5/02461; H01S 5/026; H01S 5/125

(57) ABSTRACT

An isolation section that provides thermal isolation between a laser region and an integrated optical element included in a waveguide-based optical device is disclosed. A semiconductor optical amplifier may further be included between the laser region and the integrated optical element. An additional isolation section may be included between the laser region and the semiconductor optical amplifier in certain cases.

### INCORPORATION BY REFERENCE TO ANY PRIORITY APPLICATIONS

This application claims the benefit of priority of U.S. Provisional Application No. 63/481,533 titled “ISOLATION USED FOR INTEGRATED OPTICAL SINGLE MODE LASERS” (Docket No. FREDOM.032PR), which was filed on Jan. 25, 2023, the entire disclosure of which is incorporated herein by reference.

### BACKGROUND

### Field of the Invention

Various embodiments of this application relate to the integrated optical devices and systems, and in particular, lasers integrated with other optical components.

### Description of the Related Art

Semiconductor waveguide lasers may be integrated with other optical components via waveguides on a semiconductor substrate. Such optical components may include, for example, modulators, shutters, attenuators, amplifiers, or other devices that receive a time varying electrical signal and generate heat as a result of application of this electrical signal. In some cases, that heat may affect the operation of the laser. The heat may for example, cause expansion of the gratings forming the laser cavity, variation of a refractive index of the laser cavity, a change in the band gap or other physical characteristics of the gain medium of the laser, an thereby change the wavelength of light generated by the laser.

### SUMMARY

Various designs described herein include an isolation section that provides thermal isolation between a laser region (or section) and an integrated optical element included in a waveguide-based optical device. This isolation section may reduce thermal crosstalk or heat transfer between the integrated optical element and the laser section. Additionally, the isolation section may reduce electrical crosstalk or charge transfer between the integrated optical element and the laser section. A semiconductor optical amplifier may further be included between the laser region and the integrated optical element to counter optical loss incurred with propagation of the laser light through the isolation section. An additional isolation section may be included between the laser region and the semiconductor optical amplifier in certain cases to reduce thermal crosstalk or heat transfer between the semiconductor optical amplifier and the laser region.

In some implementations, the integrated optical element comprises a component to which electrical power is applied that thereby produces heat. In various designs, for example, the integrated optical element includes at least one electrode, possibly two, such that the integrated optical element can receive an electrical signal or electrical power. In some implementations, the integrated optical element comprises an electro-optic element such as shutters, attenuators, amplifiers, or modulators. The integrated optical element may comprise, for example, semiconductor material to which one or more electrodes are disposed with respect thereto to apply electrical power to the integrated optical element. In some implementations, the integrated optical element comprises an electro-optic or optoelectronic element configured receive an modulation signal (e.g., an electric signal) and to modulate the intensity of light transmitted through the integrated optical element using the modulation signal. In various implementations the modulation signal may modulate at least one of attenuation, amplification, or absorption of light transmitted through the integrated optical element. In some examples, the modulation signal may modulate amplification and absorption of light transmitted through the integrated optical element such that the combined effect of the amplification and absorption increases a modulation depth or (dynamic range) of the resulting signal and/or a dynamic range of the corresponding optical system or laser system.

In some cases, the electrical power applied to the integrated optical element, can be time independent. For example, the integrated optical element can be an optical amplifier that provides a constant optical gain.

In some cases, the electrical power applied to the integrated optical element, can be time varying. For example, a time varying electrical signal may be applied to the integrated optical element. As a result, a time varying transfer of heat to the laser region may be produced with the integrated optical element, which may comprise a shutter, a modulated (or switched) attenuator, a modulated (or switched) optical amplifier (e.g., semiconductor optical amplifier), switch, or a modulator, acting as a time varying heat source.

Example embodiments described herein have several features, no single one of which is indispensable or solely responsible for their desirable attributes. Without limiting the scope of the claims, some of the advantageous features will now be summarized.

### BRIEF DESCRIPTION OF THE DRAWINGS

In the following description of the various embodiments, reference is made to the accompanying drawings which form a part hereof, and in which is shown by way of illustration various embodiments of the device. It is to be understood that other embodiments may be utilized and structural changes may be made.

FIG. 1A is a side cross-sectional view of an example of a semiconductor chip including a semiconductor laser (or laser region) and an integrated optical element such as a shutter or modulator. The semiconductor chip is shown on a chip carrier, which may be a heat sink and/or may be disposed over a heat sink. The laser region and the integrated optical element are separated by an isolation section to reduce thermal cross-talk and/or heat transfer therebetween (e.g., a modulated or time varying transfer of heat from the integrated optical element to the semiconductor laser).

FIG. 1B is a top view cross-sectional view of the semiconductor chip shown in FIG. 1A.

FIG. 2A is a side cross-sectional view of an example of a waveguide-based optical device (e.g., a semiconductor chip) including a semiconductor laser and an integrated optical element such as a shutter or modulator which can be a time varying source of heat. As in the example shown in FIG. 1A, the laser region and the shutter or modulator are separated by an isolation section thereby reducing thermal crosstalk or heat transfer, for example, from the integrated optical element. Additionally, in the optical device shown in FIG. 2A, a semiconductor optical amplifier (SOA) is between the laser region and the isolation section to counter loss incurred by propagation through the isolation section. The SOA may enable the length of the isolation section to be increased.

FIG. 2B is a top cross-sectional view of the semiconductor chip shown in FIG. 2A.

FIG. 3A is a side cross-sectional view of an example of an optical device (e.g., a semiconductor chip) including a semiconductor laser and an integrated optical element such as a shutter or modulator. As in the example shown in FIGS. 2A, the laser region and the integrated optical element are separated by an isolation section, here, the first isolation section, and the laser region and the first isolation section are separated by a semiconductor optical amplifier. Additionally, in the design shown in FIG. 3A, a second isolation section is between the laser region and the semiconductor optical amplifier to reduce thermal cross-talk or heat transfer therebetween. The second isolation section may for example allow for more electrical current to be injected into the SOA to thereby provide more gain and enable the first isolation section to be longer.

FIG. 3B is a top view of the semiconductor chip shown in FIG. 3A.

FIG. 4A is a top view of an example of a waveguide-based optical device (e.g., a semiconductor chip) including a dual output semiconductor laser and integrated optical elements such as shutters or modulators on opposite sides of the dual output semiconductor laser. Respective integrated optical elements are optically coupled and connected to output ports on opposite sides of the dual output semiconductor laser to receive laser light from the respective output. The dual laser output laser region and the integrated optical elements are separated by respective isolation sections to reduce thermal cross-talk between the dual laser output laser region and the respective integrated optical elements on the opposite sides of the dual output laser.

FIG. 4B is a top view of an example semiconductor chip including a dual output semiconductor laser and integrated optical elements on opposite sides of the dual output semiconductor laser. Respective integrated optical elements are optically coupled and connected to output ports on opposite sides of the dual output semiconductor laser to receive laser light from the respective output. The dual laser output laser region and the integrated optical elements are separated by respective pairs of SOAs and isolation sections to reduce thermal cross-talk between the dual laser output laser region and the respective integrated optical elements on the opposite sides of the dual output laser.

FIG. 4C is a top view of an example semiconductor chip including a dual output semiconductor laser and integrated optical elements on opposite sides of the dual output semiconductor laser. Respective integrated optical elements are optically coupled and connected to output ports on opposite sides of the dual output semiconductor laser to receive laser light from the respective output. The dual laser output laser region and the integrated optical elements are separated by respective sets of second isolation sections, SOAs, and first isolation sections on opposite sides of the laser region to reduce thermal cross-talk between the dual laser output laser region and the respective integrated optical elements on the opposite sides of the dual output laser.

FIG. 5 is a side cross-sectional view of a waveguide-based optical device (e.g., a semiconductor chip) mounted on a laser chip carrier in a flipped configuration wherein the laser region and integrated optical element are between the substrate and the laser chip carrier.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied using a variety of techniques including techniques that may not be described herein but are known to a person having ordinary skill in the art. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein. It will be understood that when an element or component is referred to herein as being “connected” or “coupled” to another element, it can be directly connected or coupled to the other element or intervening elements may be present therebetween. For clarity of description, “reflector” or “mirror” can be used interchangeably to refer to an optical element and/or a surface having a reflectivity greater than or equal to about 1% and less than or equal to 100%. For example, an optical element and/or a surface having a reflectivity greater than or equal to about 1% and less than or equal to 99%, greater than or equal to about 10% and less than or equal to 90%, greater than or equal to about 15% and less than or equal to 80%, greater than or equal to about 20% and less than or equal to 70%, greater than or equal to about 30% and less than or equal to 60%, or any value in any range/sub-range defined by these values can be considered as a reflector or mirror. It will be understood that “light having single wavelength”, “laser light having single wavelength”, “single wavelength light” or “single wavelength laser light”, can be light comprising wavelengths within a continuous wavelength or frequency band (e.g., a narrowband) centered around a center wavelength (or center frequency).

Various designs that address some of the issues such as thermal crosstalk and heat transfer described above are disclosed herein. Certain embodiments described herein provide optical devices and systems that can benefit from one or more isolation section and/or isolation layer or region between a component that generates heat and an optical component, such as a laser, that can be affected by heating. In particular, optical devices and systems are disclosed herein that comprise an isolation section (or region), with or without an isolation layer therein, that reduces thermal crosstalk from an integrated optical element that produces heat, via ohmic heating or optical absorption, as a result of receiving electrical or optical power. The integrated optical element may include a modulator, a shutter, a temporally modulated (or switched) attenuator or absorber, or a temporally modulated (or switched) optical amplifier (e.g., semiconductor optical amplifier), that is electroded to receive electrical power and produces heat as a result. In some cases, the integrated optical element may generate heat as a result of absorbing an optical power generated by the electrical power. A modulator, a semiconductor optical amplifier (SOA), an attenuator, an absorber, or shutter may be driven with a time varying signal and thus be a source of heat wherein the amount of heat produced (e.g., by ohmic heating or optical absorption) and potentially transferred is time-varying. In some embodiments, the integrated optical element (e.g., an SOA) can be configured to be forward biased and reverse biased during a modulation period or cycle. In some such embodiments, the time varying signal (also referred to as modulation signal) provided to the integrated optical element may be configured to have a first polarity to forward bias the integrated optical element during a first portion of the modulation period or cycle and a second polarity to reverse bias the integrated optical element during a second portion of the modulation period or cycle. In some examples, where the time varying signal is a periodic signal a modulation period can be the period (e.g., 1/frequency) of the periodic signal.

In some examples, where the time varying signal is an aperiodic signal a modulation period (or switching period) can be a pulse duration or a time interval between two immediately subsequent waveforms that are not identical. In some cases, when the integrated optical device is used as an optical switch, a modulation period can be a time interval from the onset of an ON state to the onset of the immediately subsequent ON state with an OFF state in between. In some examples, the time varying signal may comprise a periodic waveform having a plurality of substantially equal modulation periods. In some examples, the time varying signal may comprise an aperiodic waveform having a plurality of modulation periods, where one or both temporal length and a waveform portion (e.g., shape, amplitude and/or magnitude of the waveform) of at least two modulation periods are different. In some embodiments, the time varying signal (e.g., aperiodic time varying signal) may be received from a network or circuit and can be associated with (e.g., controlled or selected by) a user selection or user interaction with an interface. In some such embodiments, a modulation signal may comprise randomly distributed modulation periods comprising similar or different (e.g., different shapes and/or magnitudes) waveforms during different modulation periods. In some cases, when the integrated optical element 103 comprises an SOA a digital signal (e.g., an aperiodic digital signal), may be configured to forward bias the SOA during an ON state and reverse bias the SOA during an OFF state. In some other cases, when the integrated optical element 103 comprises an SOA the digital signal (e.g., an aperiodic digital signal), may be configured to forward bias the SOA during an OFF state and reverse bias the SOA during an ON state. In some embodiments, where the aperiodic signal comprises a digital signal, the ON state can be a logic 1 state and the OFF state can be logic 0 state. In some embodiments, the ON state may be associated with a high optical transmission period and OFF state may be associated with a low optical transmission period.

In some embodiments, the time varying signal may be generated by an electronic circuit that can sink and source electric current during different portion of a modulation period. For example, the electronic circuit may comprise a bipolar (or four-quadrant) power supply configured to provide positive and negative output voltages during different portions of a modulation period and source and sink the resulting electric currents. In some embodiments, driving the integrated optical element with such a modulation signal may increase the dynamic range and/or modulation depth of the resulting modulated optical signal compared to a signal (e.g., a unipolar signal) that either solely forward biases or solely reverse biases the integrated optical element during a modulation period.

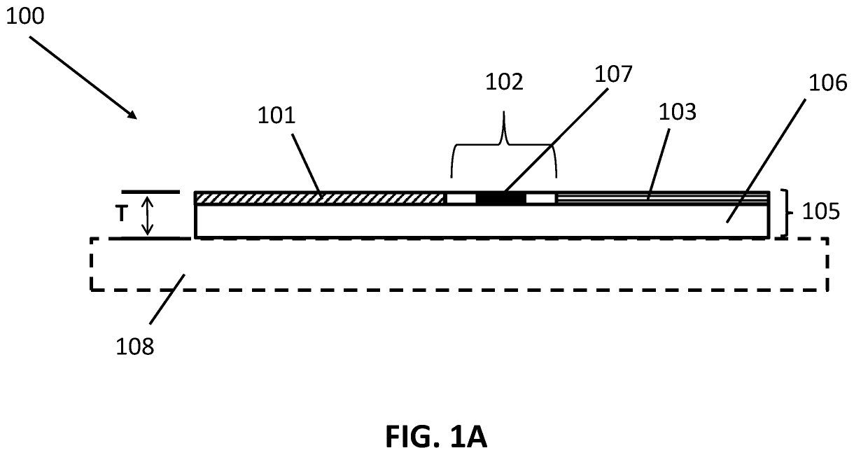

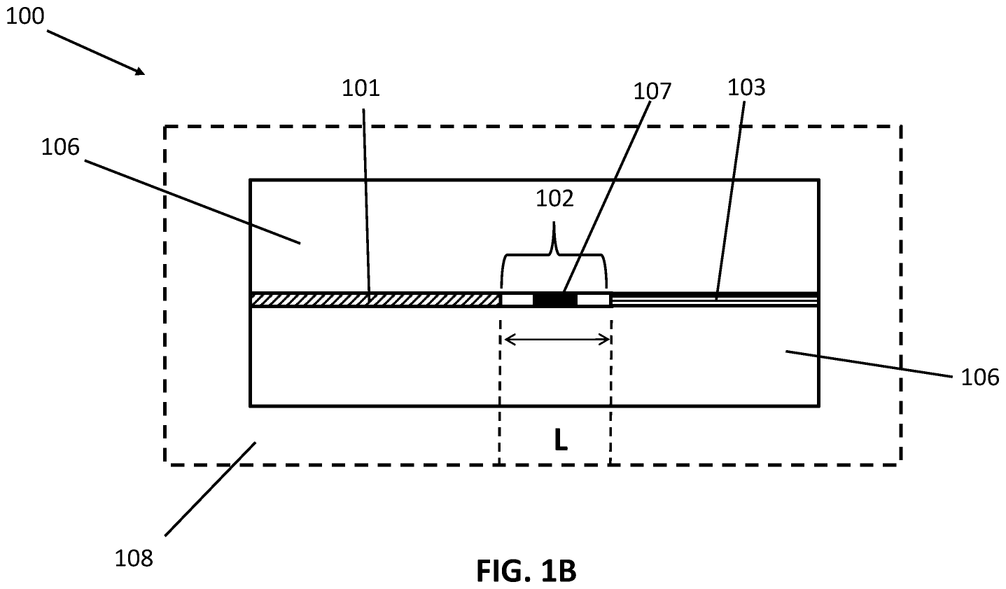

FIGS. 1A and 1B show a side cross-sectional view and a top view of a waveguide-based optical device 100 comprising a laser section (or laser region) 101, an isolation section 102, and an integrated optical element 103, wherein the isolation section is between the laser region and the integrated optical element. The integrated optical element 103 may generate heat. The isolation section (or region) 102 may be configured to reduce transfer of heat from the integrated optical element 103 to the laser section 101 to reduce the effect of heat produced by the integrated optical element on the laser section.

The waveguide-based optical device 100 comprising a laser section 101, an isolation section 102, and an integrated optical element 103 is shown as part of a semiconductor chip 105 (also referred to as laser chip). For example, in some cases, two or all three of the laser section 101, the isolation section 102 or the integrated optical element 103 may be monolithically fabricated (e.g., epitaxially grown) on a single semiconductor substrate 106. In some cases, the semiconductor waveguide laser 101, the isolation section 102, and/or the integrated optical element 103 may be bonded to the semiconductor substrate 106. The semiconductor chip 105 may comprise a semiconductor substrate 106 having one or more layers, for example, a plurality of layers thereon (the combination of substrate with laser thereon referred to as 105). The layers may comprise semiconductor as well. In various implementations, the semiconductor may comprise III-V semiconductor material. Various layers may be doped and may be doped differently from each other. The semiconductor chip 105 may comprise Al, In, Ga, As, P in various layers and as one or more compounds. In some cases, at least a layer or region of the semiconductor chip 105 may comprise a dopant such as Silicon, Zinc, Carbon, Sulphur, Boron, and the like. The substrate may comprise GaAs, InP, Silicon, Silicon Carbide, Sapphire or other materials. The devices may include quantum wells, or quantum dots. In some implementations the substrate 106 comprises an n-doped or n-type semiconductor having one or more n-doped semiconductor layers thereon. One or more P-doped or p-type semiconductor layer may be formed on the n-type material to form a junction therebetween. Other configurations are possible.

The laser section 101 may comprise a semiconductor waveguide laser. In some implementations, the laser section 101 may comprise an active waveguide having a top cladding layer, a core layer, and a bottom cladding layer. In some designs, the waveguide may comprise a ridge waveguide, for example, where upper cladding function is provided by air and the lower cladding need not be a separate layer of material from the core region produced by the ridge. Other configurations and types of waveguides, such as buried heterostructures, may be employed. In various implementations, the core layer or core region may comprise material configured to provide optical gain upon being pumped (e.g., upon receiving injection current). Likewise, at least one electrode, e.g., a pair of electrodes, may be included in the laser section 101 to apply electrical power to the gain region to pump the waveguide laser. For example, a laser region electrode may extend over at least a portion of the laser region and another electrode may be beneath the substrate 106. Electronics may be configured to apply a voltage across the laser region electrode and the electrode beneath the substrate 106 possible to forward bias the semiconductor junction and/or to inject current into and pump the laser. In various designs, the laser region electrode is isolated and does not extend into the isolation section and or contact an electrode associated with the integrated optical element. In some implementations, however, the electrode beneath the substrate 106 may extend across the isolation section and/or the integrated optical element and may comprise a common grounded electrode, however, other configurations, e.g., with electrically isolated electrodes on the substrate side, are possible. For example, an electrode beneath the substrate may include a first section beneath the laser section 101, and a second section beneath the optical element 103, where the first and the second sections are electrically isolated.

The semiconductor laser (laser section) 101 may comprise two optical reflectors that together form a laser cavity that, in some cases, supports narrow linewidth optical resonance. The first reflector may be disposed at or proximal to or near a first end of the laser waveguide or waveguide portion (e.g. active waveguide portion) and the second reflector may be disposed at or proximal to or near a second end of the laser waveguide or waveguide portion (e.g. active waveguide portion). In some cases, one or both optical reflectors may comprise (e.g., distributed Bragg gratings (BGs) also referred to as distributed Bragg reflectors (DBRs) or Sampled Grating Distributed Bragg Reflectors also referred to as SG-DBR). In some cases, one of the reflectors can be a cleaved facet. In some cases, one of the reflectors can be a DBR and the other an SG-DBR. In some cases, at least one of the reflectors may comprise an etched notch or a region having a refractive index profile engineered to provide optical reflection.

In some implementations, the laser section 101 may comprise a distributed feedback (DFB) laser which may comprise, for example, a single distributed grating. The DFB laser may be configured to generate light with a narrowband (e.g., less than 1 KHz, less than 1 MHz, or less than 1 GHz) around a center wavelength in some cases.

In some embodiments, a semiconductor waveguide laser may comprise a single mode laser (e.g., a semiconductor laser) configured to generate narrow band laser light having a center wavelength. The center wavelength may be within the O-band (e.g., between 1260 nm and 1360 nm), C-band (e.g., between 1530 nm and 1565 nm), or other optical communication bands (e.g., E-band, S-band, L-band, and U-band) for some designs. The center wavelength can be from 400 to 600 nm, from 600 to 800 nm, from 800 to 1100 nm, from 1100 to 2100 nm, or any ranges formed by these values or larger or smaller values. The wavelength may also be in the 2 μm to 10 μm range. In some examples, a narrow band laser may have bandwidth from 1 Hz to 1 KHz, from 1 KHz to 1 MHz, from 1 MHz to 50 MHz, from 50 to 100 MHz, from 100 MHz to 1 GHz, or any range formed by any of these values or may be possibly larger or smaller.

In some embodiments, a laser source may comprise one or more features of the laser sources discussed in U.S. Pat. No. 10,355,451, titled “Laser with Sampled Grating Distributed Bragg Reflector”, filed on Apr. 25, 2018 and issued on Jul. 16, 2019 (Attorney Docket No. FREDOM.015A), U.S. patent Application No. 62/901,089 filed on Sep. 16, 2019 titled “Tunable Laser with Active Material on at Least One End for Monitoring Performance” (Attorney Docket No. FREDOM.023PR), and U.S. patent application Ser. No. 17/021,993 filed on Sep. 15, 2020, titled “Tunable Laser with Active Material on at Least One End for Monitoring Performance” (Attorney Docket No. FREDOM.023A), which are each hereby incorporated herein in their entirety by reference, for example, to provide various wavelength tunable laser designs.

In some cases, the laser section 101 and/or semiconductor laser waveguide may be fabricated or formed in or on a laser chip 105. In various implementations described herein, the laser chip 105 comprises the semiconductor laser. The laser chip 105 may comprise the substrate 106 having one or more semiconductor layers thereon including an active waveguide and gain material. The laser section 101 and/or laser chip 105 may be mounted on, for example, bonded to, a laser chip carrier 108 in various designs. In some cases, the laser section 101 and/or laser chip 105 may be soldered or glued to the laser chip 105 (e.g., using epoxy). In some cases, the laser section 101 and/or laser chip 105 may be directly bonded to the laser chip 105 using thermocompression bonding, or other methods. The laser chip carrier 108 may comprise metal, semiconductor and/or dielectric materials. In various examples, the carrier chip may comprise copper, kovar Al, AlN, AlO₂, SiC, Si, SiO₂, other ceramics, glasses, or polymers. In some cases, the laser chip carrier 108 may include electrical interconnections (e.g. a metallic via and/or trace) for electrical routing. For example, the electrical interconnections may route an electrical signal from one or more sources to the laser section 101 and the optical element 103. In some cases, the laser chip 108 carrier may comprise a printed circuit board (PCB). Semiconductor layers may be epitaxially grown on the semiconductor substrate 106, comprising a wafer that may be diced or cleaved. These one or more of these semiconductor layers maybe form the semiconductor waveguide laser including the active waveguide. For example, some of these layers may form an upper cladding, core and lower cladding and one or more of these layers may comprise gain material the provides optical gain when electrical pumped. In some implementations, one or more of the layers may for different types of waveguides such as a ridge waveguide. In various implementations, the layers on the substrate 106 form a p-n junction that can be forward biased to provide optical gain, or that can be reverse biased to provide optical absorption. The components of various designs disclosed herein can be fabricated using a wide variety of materials or combinations of materials some of which may exhibit the gain, optical activity, and/or photocurrent absorption.

The integrated optical element 103 may comprise at least one waveguide portion for propagation of laser light from said laser section 101. In some implementations, the integrated optical element 103 comprises multiple waveguide portions such as for example in a Mach-Zehnder modulator or electro-absorption modulator. This at least one waveguide portion of the integrated optical element 103, may comprise a top cladding layer, a core layer, and a bottom cladding layer. In some implementations, this at least one waveguide portion may comprise a ridge waveguide, a buried waveguide, or possibly another type of waveguide. This at least one waveguide portion of the integrated optical element 103 may be optically connected to the active waveguide portion of the laser section 101 to receive light, for example, from the active waveguide portion of the laser section 101. In various embodiments, the laser section 101 and the integrated optical element 103 may be monolithically fabricated (e.g., epitaxially grown) on a single semiconductor layer or plurality of layers on the laser chip 105. The laser chip 105 may be mounted or attached, e.g., bonded, to the laser chip carrier 108 in some cases.

The integrated optical element 103 may comprise active material and/or electro-optic material for example that may have an absorption or an index of refraction that can be modulated by applying an electrical signal thereto. For example, the integrated optical element 103 may comprise a p-n junction that can be reverse biased with application of a reverse bias voltage to induce increased optical absorption or forward biased with application of an injection current, to induce optical gain. Accordingly, the integrated optical element 103 may comprise an attenuator such as a variable attenuator or absorber (e.g., an electrically controlled attenuator) or a modulator (e.g., an electro-optic modulator). In some cases, the integrated optical element 103 may comprise an SOA that can be forward and/or reverse biased. In some such cases, the SOA may be used to modulate or switch the amplitude of light. It may produce gain or it may absorb light or may generate photocurrent. The integrated optical element 103 may also comprise electro-optical material whose index of refraction varies with applied voltage. Likewise, the integrated optical element 103 may potentially be configured to alter or modulate the phase of the light received. The attenuator and/or modulator may be voltage controlled. The waveguide-based optical device 100, and in particular, the integrated optical element 103 may be configured to receive a time varying electrical signal to control and/or induce the optical modulation (e.g., optical amplitude modulation). In some implementations, the integrated optical element 103 comprises a semiconductor junction that can be reverse biased depending on the electrical signal applied thereto to vary the absorption and/or attenuation of the integrated optical element and light passing thereto. The integrated optical element 103 may thus include at least one electrode to receive the electrical signal and apply electrical current and/or voltage to the active material of the integrated optical element. In some designs, for example, two electrodes are configured to apply a voltage across active or electro-optical material of the integrated optical element. One electrode may be over a portion of the integrated optical element 103 and be electrically isolated from one or more other electrodes on the waveguide-based optical device 100 such as from the electrode for the laser section 101. In some implementations a common, e.g., ground, electrode is underneath the substrate 106 and the voltage can be applied between the electrode for the integrated optical element 103 and the common electrode. These electrode for the integrated optical element 103 may be electrically connected to electronics configured to apply an electrical signal to the electrode.

Application of an electrical signal to the integrated optical element 103, e.g., attenuator, shutter, or modulator, may also produce heat. This heat may be time varying discussed above as a time varying electrical signal may be applied to the integrated optical element. This heat may travel to the laser section 101 and may affect the operation of the semiconductor waveguide laser, for example, by causing a shift in the operating wavelength of the laser. A reflector and/or grating (e.g., DBR or DFB) included in the laser section 101 may receive thermal energy from the integrated optical element 103 to which electrical power is applied. The thermal energy or heat may cause the grating to expand changing the grating spacing and thereby the transmitted and/or reflected wavelength(s) through or by the grating. In some cases, the thermal energy may cause a change of the refractive index, bandgap, and/or other physical parameters of the grating or the laser cavity, so as to change a wavelength content or power of the light output by the laser section 101. Heating from integrated optical element 103 can thus cause a change in the temperature of the grating or laser cavity and thereby shift the wavelength of the laser and laser light output therefrom. This effect can be time varying as the amount of heat produced may vary with time as the electrical signal applied to the integrated optical element 103, such as a modulator, may be time varying.

In various implementations, the laser section 101 and the integrated optical element 103 may be spatially separated by a distance to reduce thermal crosstalk or heat transfer between the laser section (e.g., a DBR or a DFB laser section) and the integrated optical element (e.g., a variable attenuator, modulator or electrically controlled shutter). For example, the laser section 101 and the integrated optical element 103 may be separated by the isolation section 102. In some cases, the isolation section 102 may comprise a passive waveguide (e.g., a waveguide portion having a bandgap larger than of the laser section 404 and the optical amplifier section 406), or the active waveguide of the laser section 101 and/or the integrated optical element 103. In various implementations, however, an electrical signal is not applied to the isolation section 102. The waveguide portion of the isolation section 102 may be configured not to receive an electrical signal or electrical power applied thereto. Accordingly, the isolation section 102 need not have a pair of electrodes configured to apply a voltage thereto or inject a current therein or does not have electronics configured to apply a voltage to the isolation section or inject a current into the insolation section. For example, in some implementations the isolation section 102 may not have a top electrode. Other configurations, however, are possible.

In various implementations, the isolation section 102 comprises a waveguide portion that does not generate heat and is sufficiently long to reduce transfer of heat, from the integrated optical element 103 to the laser section 101, or vice versa (e.g., via the isolation section 102 or the corresponding region of the substrate 106 underneath the isolation section 102). In some cases, the length of the isolation section 102 (and the waveguide portion of the insolation section) may be longer than 50% of a thickness of the waveguide region of the optical device 100 (e.g., an active or passive waveguide region of the laser section 101, isolation section 102, and/or the integrated optical element 103). In some designs, the length of the isolation section 102 may be longer than 50% of the thickness, T, of the laser chip 105. In some cases, the length of the isolation section 102 may be longer than 50% of the combined thickness of the active waveguide and the substrate 106 of the laser chip 105 on which the laser waveguide is fabricated or formed and any intervening layers. In some designs, the length of the isolation section 102 may be longer than 50% of the combined thickness of the laser chip 105 and any layers between the laser chip and the chip carrier/heat sink 108 beneath the laser chip.

For example, in some implementations, the length of an isolation section 102 may be N times larger than a chip thickness, T, and N can be from 0.3 to 1, 0.5 to 1, 1 to 2, 1 to 3, 1 to 4, 1 to 5, 5 to 10, 10 to 15, or 15 to 20, or any range formed by any of these values or larger or smaller, for example, in some implementations to obtain a desired thermal isolation level. In some cases, the thickness of the isolation section 102 may be N times the thickness, T, of the laser chip 105, a thickness between an active region of the laser section 101 or the integrated optical element 103 to the top of the laser chip carrier 108, a distance from a top cladding of an active waveguide to the top of the laser chip carrier 108, or a distance from a top cladding of the active waveguide to the bottom of the bottom cladding of the active waveguide. Accordingly, in various implementations the isolation section 102 may be at least 0.5 or greater than 0.5 or at least 1.0 or greater than 1.0 or at least 1.5 or greater than 1.5 or at least 2.0 or greater than 2.0 or at least 2.5 or greater than 2.5 or at least 3.0 or greater than 3.0 or at least 4.5 or greater than 4.5 or at least 5.0 or greater than 5.0 times one or more of these thicknesses or distances, or at least 5.5 or greater than 5.5 or at least 6.0 or greater than 6.0 or at least 8.0 or greater than 8.0 or at least 10.0 or greater than 10.0 or at least 12 or greater than 12 or at least 15.0 or greater than 15.0 or at least 18.0 or greater than 18.0 or at least 20.0 or greater than 20.0 or any range formed by any of these values times any one or more of the various thicknesses and distances referenced above. Accordingly, in various implementations, the chip thickness, T, may be from 50 to 70 microns, from 70 to 90 microns, from 90 to 110 microns, from 110 microns to 130 microns, from 130 microns to 150 microns, from 150 microns to 200 microns, from 200 microns to 250 microns, from 250 microns to 300 microns, from 300 microns to 350 microns, or any range formed by any of these values or larger or smaller. In some cases, the length of the isolation section 102 can be from 30 to 50 microns, from 50 to 70 microns, from 70 to 90 microns, from 90 to 110 microns, from 110 microns to 130 microns, from 130 microns to 150 microns, from 150 microns to 200 microns, from 200 microns to 250 microns, from 250 microns to 300 microns, from 300 microns to 350 microns, from 350 microns to 400 microns, from 400 microns to 450 microns, from 450 microns to 500 microns, or any range formed by these values or larger or smaller.

With reference to FIG. 1A, the heat generated by the integrated optical element 103 is transferred to the chip carrier and/or heat sink and the laser section 101 via the substrate 106 and the layers thereon. In various implementations, when the length (L) of the isolation section 102 and/or the waveguide portion of the isolation section 102, for example, from the integrated optical element 103 to the laser section 101, is longer than the thickness of the laser chip 105 or the substrate 106, without subscribing to any particular theory, heat transport from the integrated optical element 103 to the chip carrier and/or heat sink can be more efficient than heat transport from the integrated optical element 103 to the laser region. In some examples, the chip carrier and/or heat sink may comprise metal or other thermally conductive material. Thus, with a sufficiently long isolation section 102 and/or waveguide portion of the isolation section, the transfer of heat from the integrated optical element 103 to the laser section 101 and/or vice versa, will be diminished. The isolation section 102 can thus operate as a thermal buffer or barrier in some cases.

The laser chip 105 and/or the optical element 103 may include metal contact pads having thermal conductivity. In some cases, these metal pads are strategically placed, e.g., on a top surface of the laser chip 105 to reduce or avoid thermal cross-talk between the laser section 101 and the integrated optical element 103. For instance, in some cases, metal contacts or electrodes on the laser 101 and the integrated optical element 103 may be kept apart by at least the length of the isolation section 102.

In some implementations, the isolation section 102 comprises a waveguide portion configured to transmit the laser light from the laser section 101 to said integrated optical element 103. As illustrated, the isolation section 102 is between said laser section 101 and said integrated optical element 103, and the respective waveguide portions thereof. In various implementations, the isolation section 102 comprises a waveguide portion (e.g., a core or core region) in optical communication with and/or connected to the active waveguide portion (e.g., the core or core region) of the laser section 101 and the waveguide portion (e.g., core or core region) of the integrated optical element 103. In some implementations, the waveguide portion of the isolation section 102 may comprise a material having a different bandgap (e.g., larger bandgap) compared to the active waveguide portion of the laser section 101 and/or the waveguide portion of the integrated optical element. Advantageously, for designs where the isolation section 102 has a different (e.g., larger) bandgap, the isolation section 102 may not absorb or may absorb less light output by the laser section 101 and therefore transmit with negligible attenuation or transmit more of the laser light from the laser section 101 to the integrated optical element 103 (while reducing the thermal and/or electrical crosstalk of the integrated optical element with the laser section).

In various implementations, the waveguide portion of the isolation section 102 has a constant size and shape along the length of the isolation section. For example, the size such as lateral dimension (e.g., width), vertical dimension (height), cross-section area, or any one or combination of these may change no more than e.g., ±10% for various designs. In other variations, the size such as the width of the waveguide portion of the isolation section 102 may change significantly between the laser section 101 and the optical element 103, e.g., up to a factor of 2 or 5 or 10 or more. In various implementations, the waveguide portion of the isolation section 102 has a refractive index between 3.15 and 3.5, or between 3.21 and 3.35. In various designs, the waveguide portion of isolation section 102 need not comprise a lens. In some implementations, the waveguide portion of the isolation section 102 does not comprise a gain medium or amplifier. In some implementations, the waveguide portion of isolation section 102 is not configured to transform or alter certain properties of the light (e.g., polarization, spectrum, and the like) transmitted therethrough, but allows the transmission of light from the laser section 101 to the integrated optical element and for reduction in the thermal cross-talk or transfer of thermal energy (e.g., heat) between the two. In some cases, the isolation section 102 does not increase the power of light transmitted therethrough. In some cases, the isolation section 102 can be configured to change a lateral cross-sectional area of guided light beam received from the laser section 101. In some cases, the isolation section 102 may attenuate light transmitted therethrough. In some such cases, the attenuation of light transmitted through the isolation section 102 can be less than 1%, less than 2%, less than 3%, less than 4%, less than 5%, less than 7%, or less than 10%. In some other cases, the isolation section 102 may not change a lateral cross-sectional area of guided light beam received from the laser section 101.

In some designs, the isolation section 102 may comprise a thermal isolation layer 107 (the dark shaded region within the isolation section 102 shown in FIGS. 1A and 1B) comprising material having reduced electrical and/or thermal conductivity in comparison to other surrounding areas such as other regions of the isolation section 102 or the laser section 101 and/or integrated optical element 103. The thermal isolation layer 107 may reduce thermal cross-talk between the laser section 101 and the optical element 103. Additionally, the thermal isolation layer 107 may reduce electric cross-talk between the laser section 101 and the optical element 103. In some implementations, the length of the isolation layer 107 can be smaller than or as large as the isolation section 102 (e.g., when the entire isolation section 102 is ion implanted so as to reduce thermal conductivity). In designs where the isolation layer 107 is smaller than the isolation section 102 (e.g., in length), the isolation layer may have either or both lower electrical conductance and/or lower thermal conductance than other regions of the isolation section 102. In some cases, the isolation layer 107 may comprise a different material composition than other portions of the isolation section 102 or than the laser section 101 and/or integrated optical element 103.

In some examples, thermal and/or electrical communication between the laser section 101 and the integrated optical element 103 may be reduced by an isolation layer 107 comprising a smaller thermal and/or electrical conductivity than the laser section 101 or the integrated optical component 103 or the portion of the semiconductor chip 105 between the laser section and the integrated optical component or any combination of these. This isolation layer 107 may comprise a portion of the core of the waveguide portion of the isolation section 102, for example, as illustrated in FIG. 1B. In some designs, this isolation layer 107 comprises the entire core of the waveguide portion of the isolation section 102.

In some designs, the isolation layer 107 may comprise an ion implanted region of the waveguide portion of the isolation section 102 and/or the substrate on which the waveguide portion is disposed and/or the layers between the waveguide portion and the substrate and/or one or more layers above this waveguide portion or any combination of these. In certain implementations, the isolation layer or region 107 may comprise an ion implanted region where an electric impedance of the isolation section 102 is increased by implanting certain ions (e.g., H+ or deuterium).

In some implementations, at least a portion of the isolation section 102 (e.g., the isolation layer 107) may be formed by removing an upper layer of a cladding, or a contact layer, in a region of the laser chip corresponding to the isolation section 102 (or the isolation layer 107), so as to reduce electrical conductivity and/or thermal conductivity in the isolation section 102. In some cases, the laser chip may comprise an epitaxial stack including the upper, cladding, and contact layers. In some examples, a layer of the epitaxial stack may be removed by etching (e.g., dry or wet etching). In some cases, etching may comprise a selective chemistry to stop the etching once the target layer is removed. In some implementation a heavily doped layer or a layer that is more conductive than other layers (e.g., lower layers) of the laser chip or the epitaxial stack may be removed to the reduce the electrical and/or thermal conductivity of the isolation section 102 or isolation layer 107. In some cases, the amount of material removed is only in the waveguide cladding and not enough to cause scattering or reflectance loss in the waveguide that is more 0.5%.

An isolation section 102 may have a length along the longitudinal direction (e.g., along a direction extending between the laser section 101 and the integrated optical element 103) and a cross-section area perpendicular to the longitudinal direction. In some cases, the length of the isolation section 102 may be substantially equal to a distance between the sections that are being thermally and/or electrically isolated (e.g., the distance between a Bragg reflector in the laser section 101 and a heat generating integrated optical element 103 such as an integrated optical element to which electrical or optical power is applied like an attenuator, modulator, SOA, or shutter). In some examples, the length of the isolation layer or region 107 (e.g., the ion implanted region) may be from 1% to 10%, 10% to 30%, 30%-50%, 50% to 70%, or 70% to 100% of the length of the isolation section 102.

In some implementations, in addition to thermal isolation, one or both of the isolation section 102 and isolation layer 107 provide electrical isolation between the laser section 101 and the integrated optical element 103, e.g., by reducing charge transport between them.

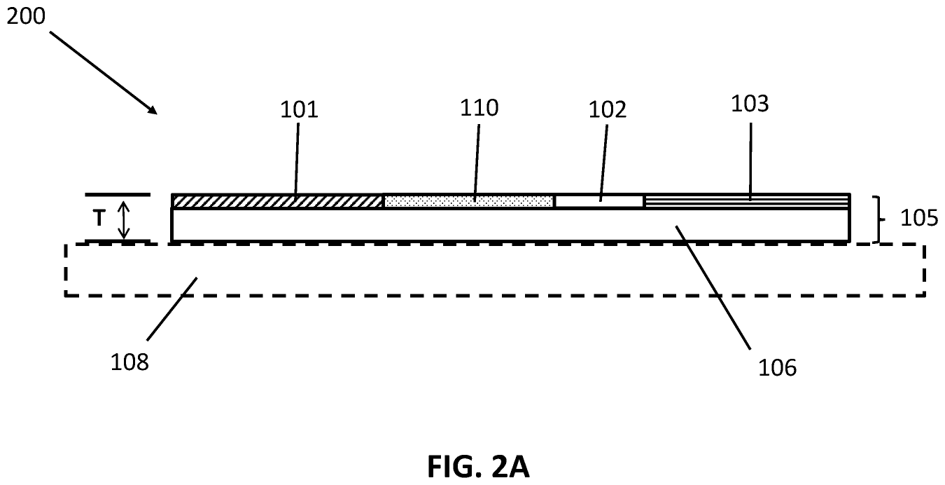

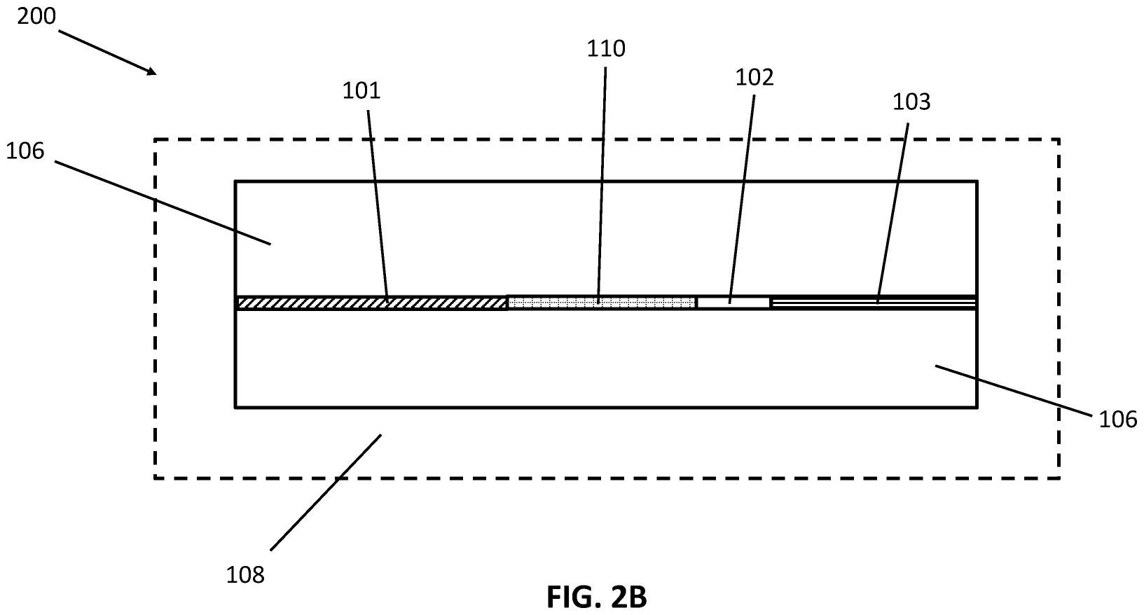

In some cases, optical loss may result from propagation of laser light from the laser section 101 through the waveguide portion of the isolation section 102. To counter at least some of this loss, the waveguide-based optical device (e.g., a semiconductor chip) 200 may further comprise a semiconductor optical amplifier (SOA) 110 between the laser section 101 and the isolation section 102 as illustrated in FIGS. 2A and 2B. The waveguide-based optical device 200 shown in FIGS. 2A and 2B comprises similar components and has similar features as discussed with reference to FIGS. 1A and 1B. For example, the waveguide-based optical device 200 includes a laser section 101 and integrated optical element 103 such as a shutter, modulator, attenuator. Accordingly, the discussions above with regard to FIGS. 1A and 1B and other discussion herein apply as well to devices that include a semiconductor optical amplifier 110, for example, between the laser section 101 and the isolation section 102 as shown in FIGS. 2A and 2B.

In some examples, the semiconductor optical amplifier 110 may comprise an active waveguide portion comprising optically active material (e.g., a compound III-V semiconductor material). In some cases, the semiconductor waveguide laser, semiconductor optical amplifier 110, isolation section 102 and/or isolation layer 107, the integrated optical element 103, or any combination of these, may be monolithically fabricated (e.g., epitaxially grown) on a single substrate. In some implementations, the semiconductor optical amplifier 110 comprises at least one semiconductor on the semiconductor substrate 106 that forms a p-n junction which can be forward biased to provide optical gain. In some designs, at least one electrode (e.g., a pair of electrodes) can be used to apply electrical power to the active material of the semiconductor optical amplifier. In some cases, the electrical power applied to the SOA 110 can be time independent. In some other cases, the electrical power applied to the SOA 110 may be substantially constant during a period at least 10, 100, 1000 times longer than a period during which the power applied to the integrated optical element 103 stays constant. In some designs, the SOA 110 may share a common pair of electrodes with the laser. This electrical power received by the SOA 110 pumps the active material to provide optical gain (e.g., time-independent optical gain) to the amplifier for light propagating therethrough. The semiconductor optical amplifier 110 may comprise an upper cladding, a core, and a lower cladding to form the active waveguide portion. In some implementations, the SOA comprises a ridge waveguide or other type of waveguide and need not have an upper cladding and/or lower cladding. The optically active waveguide portion of the SOA 110 may be connected to and in optical communication with the active waveguide portion of the semiconductor waveguide laser in the laser section 101 and receive light therefrom. The optically active portion of the SOA may also be connected to and in optical communication with the waveguide portion of the isolator region 102 such that the waveguide portion of the isolator region can receive amplified laser light from the pumped active waveguide of the SOA. In addition to amplifying the laser light generated by the laser section 101, the SOA 110 enhances thermal isolation of the laser section 101 from the integrated optical element 103 by increasing the distance between these elements.

In some implementations, this semiconductor optical amplifier 110 may be flared. The core or core region of the active waveguide of the SOA 110 may increase in width along the length of the active waveguide of the SOA.

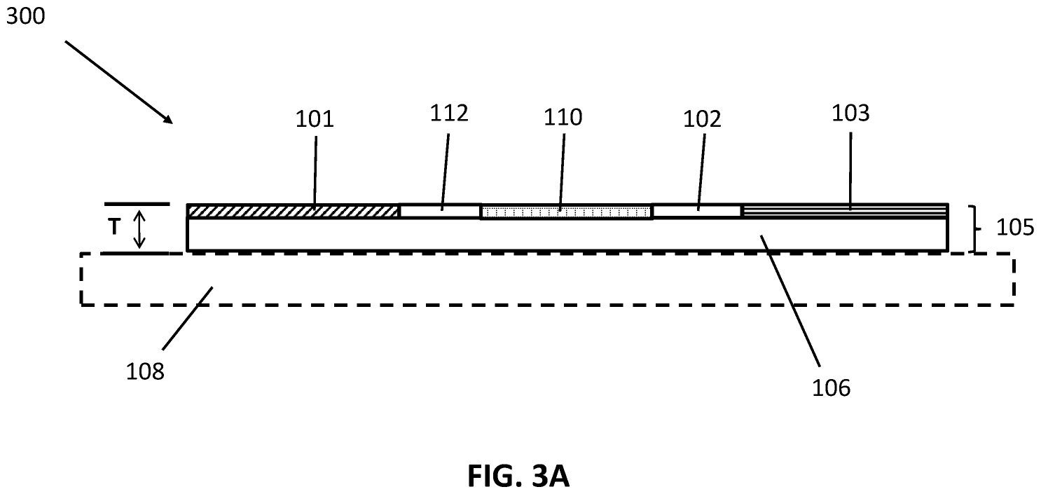

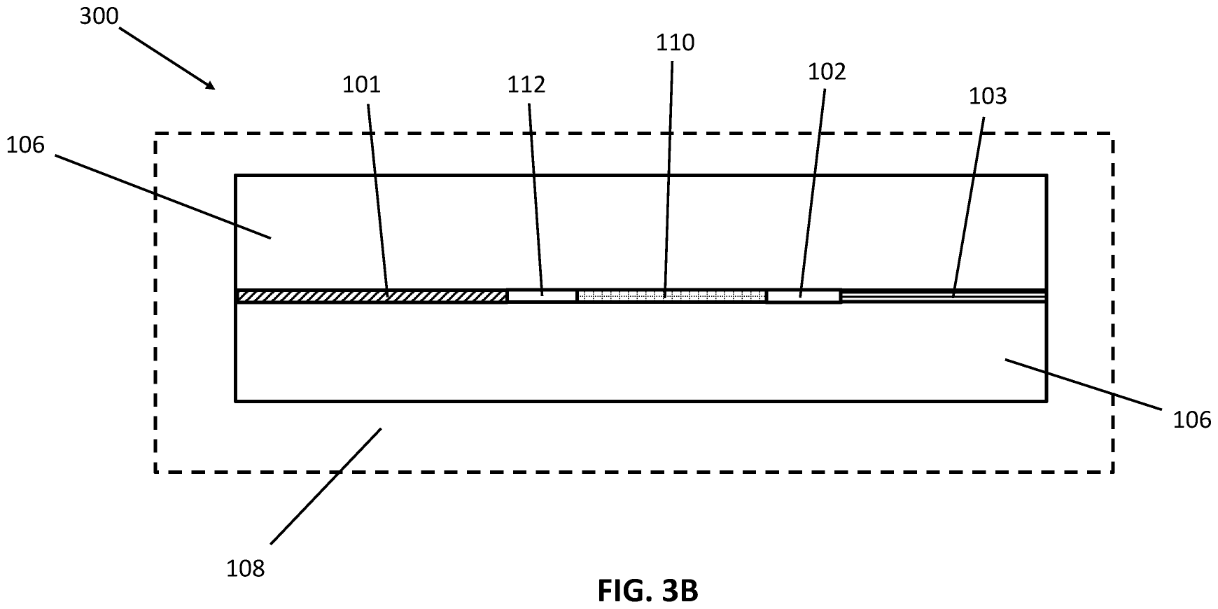

In some cases, the semiconductor optical amplifier 110 may produce heat. In some implementations, this heat is not time varying like the integrated optical element 103 which may comprise a shutter, modulator or attenuator; thus it may not cause a temporal variation in the performance of the laser section 101 or integrated optical element 103. Moreover, the elevated temperature of the SOA 110 may further reduce heat transfer laser section 101 and the integrated optical element 103. To counter the heating of the semiconductor waveguide laser, for example, heating of a grating within the laser section 101 that causes a shift in the wavelength of the laser, a second or additional isolation section (or region) 112 may be included between the SOA 110 and the laser section 101 as illustrated in FIGS. 3A and 3B. This second or additional isolation layer 112 may to reduce thermal crosstalk between the SOA 110 and the laser section 101. The additional isolation section 112 may also reduce thermal and electrical cross talk between the integrated optical element 103 and the laser section 101 1. The waveguide-based optical device 300 shown in FIGS. 3A and 3B comprises similar components and has similar features as discussed with reference to FIGS. 1A-1B and 2A-2B. For example, the waveguide-based optical device 300 includes a laser section 101 and integrated optical element 103 such as a shutter, modulator, attenuator. Accordingly, the discussions above with regard to FIGS. 1A-1B and 2A-2B and other discussion herein apply as well to devices that include a second or additional isolation section 112, for example, between the laser section 101 and the semiconductor optical amplifier 110 as shown in FIGS. 3A and 3B.

In some cases, the amount of thermal or electrical isolation or the reduction in crosstalk or heat transfer between the SOA 110 and the laser section 101 may be tailored by controlling the length of the second isolation section 112. The second isolation section 112 may comprise features described above with respect to the isolation section 102 between the laser section 101 and the integrated optical element 103 of the laser chip 105, and thus, the discussions above with respect to the isolation section 102 apply as well to the second or additional isolation section 112. In some cases, the amount of thermal energy or heat transferred between components on opposite sides of the second isolation section 112 may be reduced by increasing the length of the second isolation section 112 relative to a chip thickness (e.g., the laser chip thickness), T. As with the isolation section 102 described above, the second isolation section 112 may comprise a waveguide portion for propagating light guided therein. The second isolation section 112 may comprise a waveguide portion formed by an upper cladding, a core, and a lower cladding. In some implementations, the waveguide portion comprise a ridge waveguide or other type of waveguide. The second isolation section 112 may be formed by one or more layers formed on the semiconductor substrate 106 and possibly the semiconductor substrate itself. In various implementations, the length of the second isolation section 112 (and the waveguide portion of the second isolation section) may be at least 50% or 100% of a thickness of various structures in the waveguide based optical device. For example, in some cases, the thickness may be the thickness of the laser waveguide. In some cases, the thickness may be the thickness between the active region of the semiconductor waveguide laser 101 to the top of the laser chip carrier 108 on which the laser waveguide 1011 is disposed or mounted, e.g., between 90-150 microns below. In some cases, the thickness may be the combined thicknesses of the upper cladding layer, core layer, and the bottom cladding layer of the active laser waveguide and any intervening layer between the bottom cladding layer and the laser chip carrier 108 on which the laser chip is disposed or mounted. In some cases, the thickness may correspond to the chip thickness. In some examples, the chip thickness may be between 50-100 microns, 100-150 microns, 50-150 microns, 150-300 microns, 300 to 500 microns, or 500 microns to 1 mm or any range between any of these values or possibly larger or smaller.

In various implementations, when the length of the second isolation section 112 and/or the waveguide portion of the second isolation section 112, for example, from the semiconductor optical amplifier 110 to the laser section 101 is longer than the thickness of the chip 105, without subscribing to any particular theory, heat will flow from the semiconductor optical amplifier 110 through the chip 105, e.g., through the semiconductor substrate and the layers thereon 106, to the laser chip carrier and/or heat sink 108 (which may comprise metal or other thermally conductive material) before reaching the laser section 101. Thus, with a sufficiently long second isolation section 112 and/or waveguide portion of the second isolation section 112, the transfer of heat from the semiconductor optical amplifier 110 to the laser section 101 and/or vice versa, will be diminished. The second isolation section 112 can thus operate as a thermal buffer or barrier in some cases. The optical amplifier 110 can also act as a thermal or electrical buffer or barrier between the laser section 101 and the integrated optical element 103 in some cases. As a consequence of the reduction in cross-talk or heat transfer provided by the amplifier to the lasing region, the amplifier may be driven with more current to provide more gain, which may facilitate use of a longer first isolation section 102 as absorption of light by the isolation section 102 is at least partly compensated by the increased gain of the amplifier with additional current provided.

As described above in connection with the isolation section 102 between the laser section 101 and the integrated optical element 103, in some implementations, the second isolation section 112 may comprise sections of a waveguide comprising a semiconductor material (e.g., III-V semiconductor material). In some cases, the semiconductor waveguide lasers, second isolation section 112 and/or a second isolation layer (e.g., similar to the isolation 107 in FIG. 1A/2A) in the second isolation section, semiconductor optical amplifier 110, first isolation section 102 and/or the first isolation layer and the integrated optical element 103 may be monolithically fabricated (e.g., epitaxially grown) on a single semiconductor substrate. In some implementations, the second isolation section 112 comprises a waveguide portion configured to transmit the laser light from the laser section 101 to said SOA 110. As illustrated, the second isolation section 112 is between said laser section 101 and said SOA 110, and the respective waveguide portions thereof. In various implementations, the second isolation section 112 comprises a waveguide portion (e.g., a core or core region) in optical communication with and/or connected to the active waveguide portion (e.g., the core or core region) of the laser section 101 and the active waveguide portion (e.g., core or core region) of the SOA 110. In some implementations, the waveguide portion of the isolation section 112 may comprise a material having a different bandgap (e.g., larger bandgap) compared to the active waveguide portion of the laser section 101 and/or the waveguide portion of the SOA 110. Advantageously, for designs where the second isolation section 112 has a different (e.g., larger) bandgap, the second isolation section 112 may not absorb or may absorb less light output by the laser and therefore transmit or transmit more of the laser light from the laser section 101 to the SOA 110 with negligible attenuation (while reducing the thermal and/or electrical crosstalk of the semiconductor optical amplifier with the laser section). As discussed above, the second isolation section 112 may for example reduce the flow of heat from the semiconductor optical amplifier 110 to the laser section 101. Additionally, the second isolation section 112 and the SOA 110 together may act as a electrical and/or thermal buffer or barrier between the integrated optical element 103 and the laser 101.

In various implementations, the waveguide portion of the second isolation section 112 has a constant size and shape along the length of the second isolation section. For example, the size such as lateral dimension (e.g., width), vertical dimension (height), cross-sectional area, or any one or combination of these may change no more than, e.g., within ±10%, for various designs. In various implementations, the waveguide portion of the second isolation section 112 has a refractive index between 3.15 and 3.5, or between 3.21 and 3.35. In various designs, waveguide portion of the second isolation section 112 need not comprise a lens. In some implementations, the waveguide portion of the second isolation section 112 does not comprise a gain medium or amplifier. In various implementations, the waveguide portion of the second isolation section 112 is not configured to transform or alter the properties of the light transmitted therethrough, but allows the transmission of light from the laser section 101 to the integrated optical element 103 and for reduction in the thermal cross-talk or transfer of thermal energy (e.g., heat) between the two.

In some cases, one or both of the isolation sections (or regions) 112 or 102 can be configured to change a transverse or lateral cross-sectional area of guided light received from the laser section 101 or the SOA 110, e.g., to reduce optical coupling loss to the SOA 110 or the integrated optical element 103, respectively. For example, the isolation section 102 may comprise a tapered or flared waveguide that transforms a mode profile output by the laser 101 (FIG. 1A), or SOA 110 (FIG. 3A) to a mode profile substantially matched to the optical element 103.

In some cases, one or both of the isolation sections (or regions) 112 and 102 can be configured to change a polarization state of guided light received from the laser section 101 or the SOA 110 to reduce optical coupling loss to the SOA 110 or the optical element 103, respectively. For example, the isolation section 102 may transform (e.g., rotate) a polarization of guided light output by the laser 101 (FIG. 1A), or the SOA 110 (FIG. 3A) to a polarization for which the integrated optical element 103 is designed. In some cases, where the integrated optical element 103 is an electro-optical modulator, it may modulate (or switch) guided light having a predetermined polarization more effectively compared to light having other polarizations.

In some cases, one or both of the isolation sections (or regions) 112 and 102 may comprise a beam splitter or directional coupler that receives light from the laser section 101 (or the SOA 110), transmits at least a first portion of the received light to a first optical element and a second portion of received light to a second optical element. In some examples, one or both of the isolation section (or region) 112 and 102 may comprise a directional coupler or a Y-shape waveguide configured to receive light from an input port and split the received light between at least two output ports. In some cases, a splitting ratio between the two output ports can be from 5/95 to 50/50.

In some implementations, one or both of the isolation sections (or regions) 112 and 102 do not transform or alter a property of the light (e.g., polarization, spectrum, and the like) transmitted therethrough, but allow the transmission of light from the laser section 101 to the integrated optical element 103 and for reduction in the thermal cross-talk or transfer of thermal energy (e.g., heat) between the two. In some such implementations, one or both of the isolation sections (or regions) 112 and 102 do not increase the power of light transmitted therethrough. In some cases, one or both of the isolation sections (or regions) 112 and 102 may attenuate the light transmitted therethrough. In some implementations, one or both of the isolation sections (or regions) 112 and 102 do not change a transverse or lateral cross-sectional area of guided light received from the laser section 101. In some implementations, the isolation sections (or regions) 112 and 102 do not comprise: a grating (e.g., a Bragg grating), a beam splitter, a multiplexer, a coupler, a mode converter, a polarization controller, a polarizer, an optical filter, a tapered region, an optical amplifier, an optical modulator, photonic crystal, an optical switch, or an element that amplifies, modulates, switches, or filters the light passing through the isolation section 112 and 102. In some cases, the isolation section 102 or the isolation section 122 can attenuate light transmitted therethrough by less than 1%, less than 2%, less than 3%, less than 4%, less than 5%, less than 7%, or less than 10%.

In some implementations, the second isolation section 112, e.g., the length of the passive waveguide portion of the second isolation section, may include an isolation layer or region 107, such as described above, comprising a material having thermal and/or electrical conductance or conductivity that is less than other portions of the second isolation section 112 and/or other components or areas such as the laser region 101 and/or the SOA 110. Accordingly, the discussions above regarding the isolation layer or region 107 in the isolation section 102 shown in FIGS. 1A and 1B can equally apply to the isolation layer or region 107 in the second isolation section 112. For example, in some implementations, the isolation layer 107 comprises an ion implanted region or otherwise comprises a region having different material composition than other portions of the isolation section 110 and/or other areas or components such as the laser region 101 and/or the SOA 110. Likewise, in some cases, the isolation layer (or region) 107 may comprise a material composition different from and possibly having a lower thermal conductivity than of the laser section 101, the SOA 110, or a waveguide portion between them. The length and/or cross-sectional area of isolation layer 107 may be adjusted to reduce the thermal crosstalk and transfer of heat, for example, between the SOA 110 and the laser region 101 by a sufficient amount. In some designs the isolation section 112 and or the isolation layer 107 may be N times or larger than the any of the thicknesses referenced above, and N can be from 0.1 to 1, 0.5 to 1, 1 to 2, 1 to 3, 1 to 4, 1 to 5, 5 to 10, 10 to 15, or 15 to 20, or any range formed by any of these values or larger or smaller, for example, in some implementations to obtain a desired thermal isolation level or crosstalk reduction. Accordingly, in various implementations the isolation layer 107 in the second isolation section 112 may be at least 0.5 or greater than 0.5 or at least 1.0 or greater than 1.0 times these thicknesses (e.g., the chip thickness referenced above). In some cases, the length of the second isolation layer or region 107 can be from 1 to 10 microns, from 10 to 30 microns, from 30 to 50 microns, from 50 microns, from 50 to 70 microns, from 70 to 90 microns, from 90 to 110 microns, from 110 microns to 130 microns, from 130 microns to 150 microns, from 150 microns to 200 microns, from 200 to 250 microns, from 250 to 300 microns, from 300 microns to 400 microns, from 400 microns to 500 microns, or any range formed by any of these values or larger or smaller.

As discussed above, in some cases, an isolation layer or region 107 of the waveguide between the laser section 101 and the SOA 110 may comprise a different material (e.g., a material having a different bandgap such as a larger bandgap) compared to the laser section 101 and the SOA 110. In some cases, the isolation section 102 and/or isolation sections 112 may comprise a material compared to the laser section 101 and SOA 110. For example, the isolation section 102 and/or isolation sections 112 may comprise a material having a different bandgap (e.g., a larger bandgap) compared to a material used as gain medium in the laser section 101 and SOA 110. In some cases, the isolation section 102 and/or 112 may comprise the same material as section 101 or 110 but may not be pumped (e.g., by an injection current) to provide optical gain. In some cases, isolation section 102 or 112 may attenuate light transmitted therethrough by less than 10 dB (e.g., by 0.1 dB, 0.5 dB, 1 dB, 3 dB, or 5 dB). In some implementations, the isolation layer 107 is included in a waveguide portion of the second isolation section 112 configured to transmit the laser light from the laser region 101 to said SOA 110. Accordingly, the isolation layer 107 may be between said laser region 101 and said SOA 110, and the respective waveguide portions thereof. In various implementations, the isolation layer or region 107 comprises or is included in the waveguide portion (e.g., a core) of the isolation section 112 in optical communication with and/or connected to the active waveguide portion (e.g., the core) of the laser region 101 and the active waveguide portion (e.g., core) of the SOA 110. In various implementations, the material in the isolation layer or region 107 has reduced absorption and having a larger bandgap, for example, compared to the laser region 101 or SOA 110, may be reduce such absorption.

In various implementations, the laser section 101, SOA 110, and possibly the integrated optical element 103 may comprise electrodes that are electrically connected to electronics to provide electrical power, electrical voltage, or electrical current or any combination of these. In contrast, in various implementations, the isolation sections 102, 112 need not include such electrodes or be electrically connected to electronics that provide electrical power, electrical voltage, or electrical current. Separate (electrically isolated) electrodes may be disposed on the laser section 101 and integrated optical element 103 to independently control the electrical currents injected to each section. For example, an electrode disposed on the laser section 101 may control the current injected into the semiconductor waveguide laser (and therefore the laser output power) and an electrode disposed on the integrated optical element 103 may control the voltage applied and/or the current injected to the integrated optical element (and therefore possibly the absorption of a shutter or attenuator or the index of refraction of a modulator). Similarly, an electrode disposed on the SOA 110 may control the voltage applied to and/or the current injected into the SOA (and therefore the optical gain provided by the optical amplifier section) and an electrode disposed on the integrated optical element 103 may control the voltage applied on the integrated optical element, or the current injected to or extracted from the integrated optical element (and therefore possibly the absorption of a shutter or attenuator, the refractive index of refraction of a modulator, or an amplification of an optical amplifier). In some implementations, a common ground electrode underneath the substrate 106 may provide the second electrode for application of voltages across more than one component, e.g., across the laser section 101, the SOA 110, the integrated optical element 103 or any combination of these. In various implementations, however, the isolation section 102, 112 and/or isolation layers therein do not receive electrical power or an electrical signal such that the isolation section and/or isolation layer does not produce heat. Likewise in various implementations, the isolation sections 102, 112 and/or isolation layers therein do include a pair of electrodes or at least one electrode for applying electrical voltage and/or current. For example, the isolation section 102, 112 and/or isolation section may not include a top electrode. Or electronics is not configured to provide electrical power or signals to the isolation sections 102, 112 even if electrodes are present.

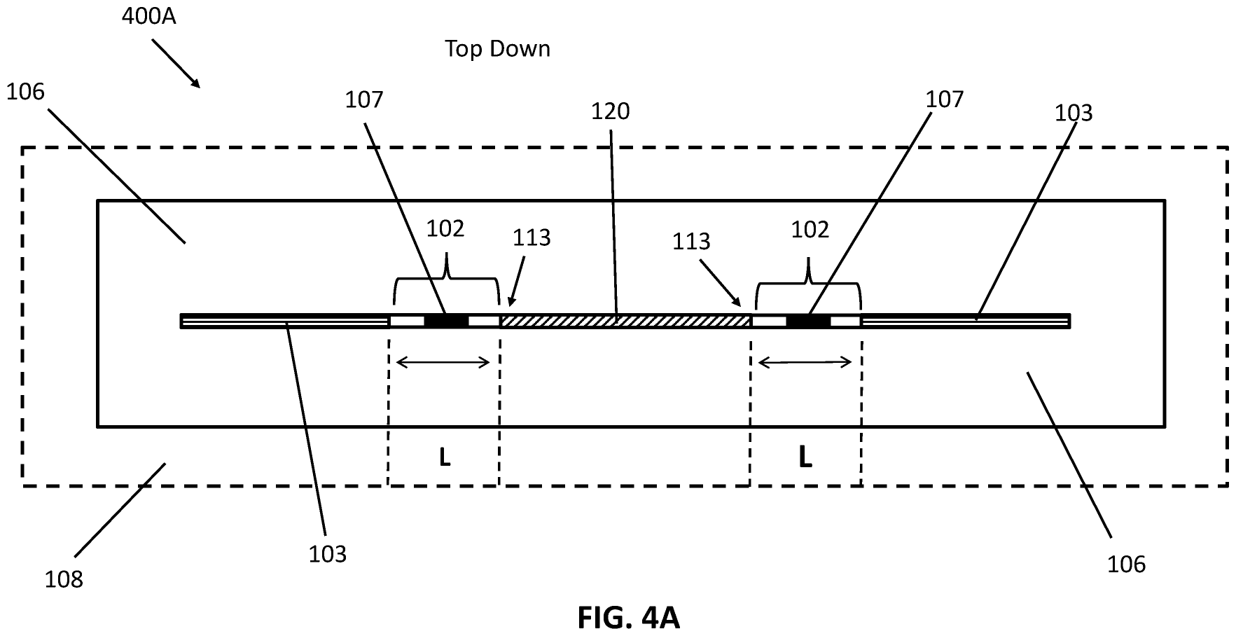

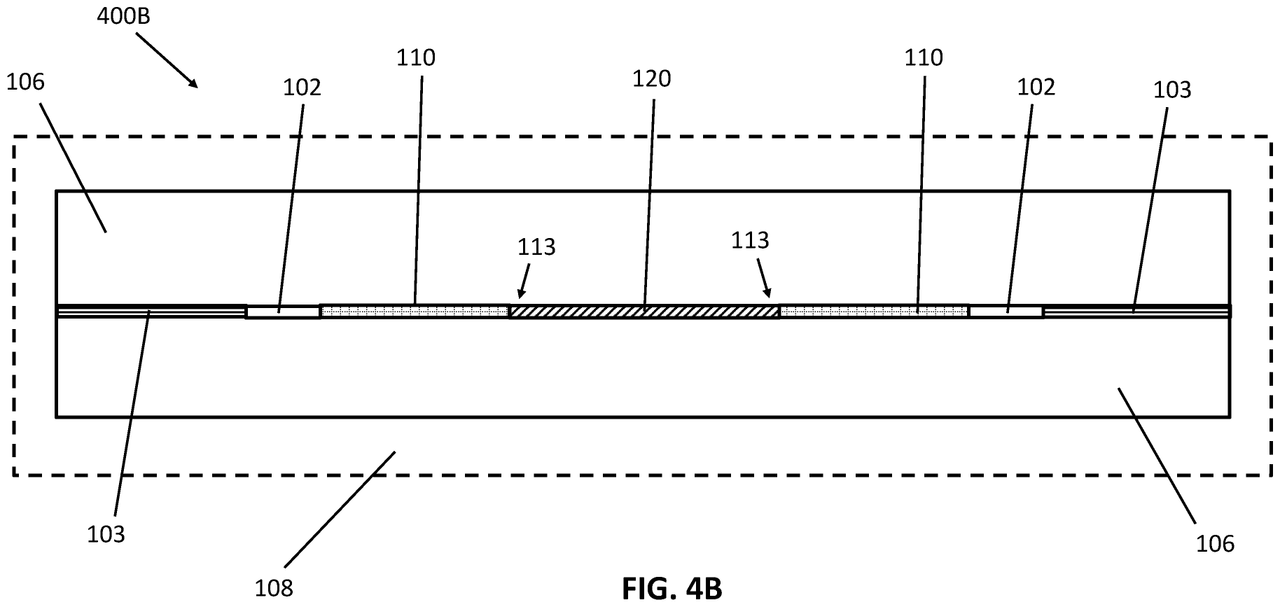

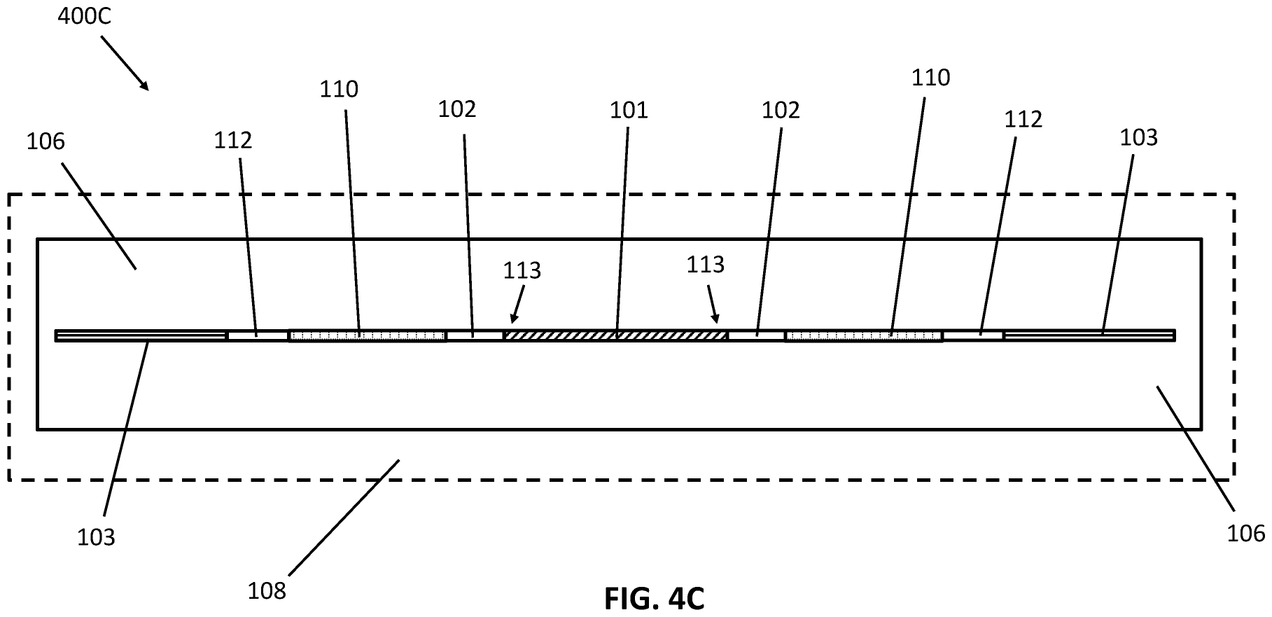

As illustrated in the example shown in FIGS. 4A, 4B, and 4C, in some cases, a laser section 120 of a waveguide-based optical device 400A/400B/400C may comprise a dual output laser and have dual outputs 113. The dual output semiconductor laser of the waveguide-based optical devices 400A/400B/400C, may be configured to generate laser light and output a portion of the light from each end 113 of the semiconductor waveguide laser. In some implementations, the light output from both sides of the dual output laser section 120 has the same wavelength or wavelengths. In various implementations, the dual output laser section 120 and the dual semiconductor laser may comprise one or more features discussed above with respect to laser section 120 and semiconductor waveguide laser described above for example in connection with FIGS. 1A-1B, 2A-2B, and 3A-3B, or elsewhere herein. As discussed, below, the dual output laser can be optically coupled to a variety of optical components and have configurations such as described above in connection with FIGS. 1A-1B, 2A-2B, and 3A-3B, or discussed elsewhere herein.

The dual output semiconductor laser in the laser section 120 may have a pair of reflectors such as distributed Bragg Grating reflectors (DBR) forming a laser cavity or may be a Distributed Feedback (DFB) laser comprising, for example, a single DFB grating. The laser section 120 may comprise a laser waveguide extending in a longitudinal direction between a first output port 113 and a second output port 113 on opposite sides of the laser. In some cases, the laser waveguide may comprise a top cladding layer, a core layer, and a bottom cladding layer. In some implementation, the laser waveguide comprises a ridge waveguide or other type of waveguide. In some such cases, the core layer or core region may comprise a gain region configured to provide optical gain upon being pumped (e.g., upon receiving injection current). In some cases, the bottom cladding layer may comprise a base material on which the subsequent layers are grown. At least a portion of the laser waveguide may be an active waveguide configured to provide optical gain upon being pumped (e.g., electrically pumped).

In some cases, the dual output laser section 120 may output a first output power from the first output port 113 and second output power from the second output port 113, which may be on opposite sides of the laser section 120. In some cases, the first and the second output powers may be substantially equal. In some cases, a ratio between the first and the second output powers may be from 0.5 to 1, from 1 to 1.5, or from 1.5 to 2 or any range formed by any of these values or higher or lower.

The dual output laser in the laser section 120 may be coupled to one integrated optical element 103 receiving one of the laser outputs, or may be coupled to two integrated optical elements 103 each receiving one of the laser outputs 113 on opposite respective sides of the dual output laser as shown in FIG. 4. In various implementations, the dual-output laser section 120 may be optically coupled to one or more integrated optical elements 103 such as attenuators, modulators, shutters, semiconductor optical amplifiers, etc. For example, in some implementations, respective integrated optical elements 103 may receive laser light from one of the laser outputs 113. Same or different types of integrated optical elements 103 may be on the first and second side of the dual-output laser and optically connected to a respective output 113 of the laser section 120. In some cases, the dual-output laser, and the integrated optical element 103 that receives light from dual-output laser are monolithically fabricated (e.g., epitaxially grown) on a single laser chip. The waveguide portion(s) of the integrated optical element(s) may be optically coupled and connected to the active waveguide portion of the dual output laser section 120.

In some cases, the thermal cross-talk or heat transfer between the integrated optical elements (e.g., modulator, shutter, attenuator, SOA, etc.) 103 and the dual laser output laser section 120 may be reduced by providing separation therebetween. Likewise, in some cases, the thermal cross-talk and/or heat transfer between an integrated optical element 103 and the dual laser output laser section 120 may be reduced due to separation therebetween. Similarly, in some cases, the thermal cross-talk and/or heat transfer between the dual laser output laser section 120 and one or both integrated optical elements 103 comprising e.g., a modulator, an optical switch, a shutter, a attenuator, SOA etc. may be reduced due to the separation therebetween. This separation may be provided by an isolation section (e.g., isolation section 102, 112), possibly an SOA and an isolation section, or possibly an isolation section, an SOA, and another isolation section such as described above, for example, in connection with FIGS. 1A-1B, 2A-2B, and 3A-3B discussed above and also discussed below in connection with waveguide-based optical devices 400A, 400B, and 400C shown in FIGS. 4A, 4B, and 4C, respectively. Isolation sections 102, for example, are shown in FIG. 4A between the laser section 120 and the respective integrated optical elements 103 on opposite sides of the laser region and optically coupled to the outputs of the laser region. Likewise, SOAs 110 and additional isolation sections 112 as shown in FIGS. 2A-2B, and 3A-3B can be included on opposite sides of the laser section 120 optically coupled and connected to respective outputs 113 on opposite sides of the laser region as shown in FIGS. 4B and 4C. FIG. 4B, for example, shows respective SOAs 110 and isolation sections 102 between the laser section 120 and the respective integrated optical elements 103 on opposite sides of the laser. FIG. 4C shows respective second isolation sections 112, SOAs 110 and first isolation sections 102 between the laser section 120 and the respective integrated optical elements 103 on opposite sides of the laser. The discussions above with regard to the integrated optical elements, 103, isolations sections 102, SOAs, 110, and second isolation sections 112 as well as the isolation layers/regions, such as in connection with FIGS. 1A-1B, 2A-2B, and 3A-3B equally apply to the integrated optical elements, 103, isolations sections 102, SOAs, 110, and second isolation sections 112 as well as the isolation layers/regions used with and optically connected to, for example, one or more outputs 113 of a dual output semiconductor lasers, such as for example, shown in FIGS. 4A-4C.

For example, as discussed above in connection with FIGS. 1A and 1B, in some designs, the dual-output laser regions 120 and the integrated optical elements 103 on either sides of the laser region 120 may be electrically and/or thermally isolated using a one or more isolation layers 107 such as shown in FIG. 4A. As discussed above, an isolation layer 107 may reduce electrical and/or thermal crosstalk between the dual-output laser and the integrated optical element (e.g., modulator, shutter, attenuator, mirror, optical amplifier, etc.) 103.

Accordingly, in some cases, a single-output or dual-output laser (e.g., a semiconductor DBR or DFB laser) of the laser section 101 or 120 that is integrated with an integrated optical element (e.g., modulator, shutter, attenuator, semiconductor optical amplifier, etc.) 103 may be separated from the integrated optical element by a distance (e.g., in a longitudinal direction along the laser waveguide) larger than half the thickness, larger than the thickness, or larger than a multiple, N, of the thickness of an optically active layer (e.g., a layer comprising III-V semiconductor material) or a waveguide layer in which the laser and/or the amplifier are fabricated or disposed, or the thickness of the laser chip or the distance from the top of the laser chip carrier 108 to the core of the waveguide or to the top of the semiconductor waveguide laser or to the top of the laser chip. In various implementations, the integrated optical element 103 may be heat generating and may have one or more (e.g., two) electrodes such that a voltage and/or current can be applied thereto, or a current may be extracted, and may be electrically connected to electronics that provide electrical power or electrical signal or any combination thereof.

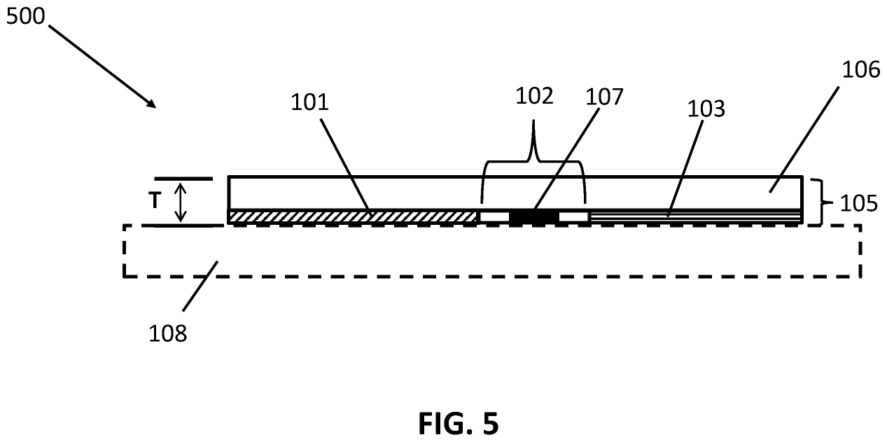

In various implementations, the semiconductor waveguide laser may be formed on a substrate 106 having a plurality of semiconductor layers between the waveguide laser and the substrate and the substrate may be mounted on a laser chip carrier and/or heat sink 108 such as shown in FIGS. 1A, 2A, and 3A. The semiconductor waveguide and the laser chip carrier and/or heat sink 108 are thus on opposite sides of the substrate 106 in some such implementations. In certain designs, however, the laser chip 105 is flipped with the waveguide laser (and, for example, laser section 101, isolation section 102, and integrated optical element 103) between the substrate 106 and the laser chip carrier and/or heat sink 108 such as shown in FIG. 5.

In some designs, the semiconductor waveguide laser comprises one or more p-type doped semiconductor layers formed on one or more n-type doped semiconductor layers formed on an n-type semiconductor substrate. Additionally, the semiconductor waveguide laser may comprise an intrinsically doped or undoped region in between the n-type and the p-type layers. In some designs, the substrate 106 is mounted on a laser chip carrier and/or heat sink 108 such that the substrate is closer to the laser chip carrier and/or heat sink than the semiconductor laser (e.g., laser section 101) is. Such a configuration, for example, is shown in FIGS. 1A, 2A, and 3A. By contrast, in some designs, the laser chip 105 is flipped and the laser chip is mounted on a laser chip carrier and/or heat sink 108 such that the semiconductor laser (e.g., laser section 101) is closer to the laser chip carrier and/or heat sink and the substrate 106 is farther from the laser chip carrier and/or heat sink 108 as shown in FIG. 5.

In various configurations where the laser chip 105 is flipped (such as shown in FIG. 5) and the laser chip is mounted on a laser chip carrier and/or heat sink 108 such that the semiconductor laser (e.g., laser section 101) is closer to the laser chip carrier and/or heat sink than is the substrate 106, the length of the isolation section 102, L, may be at least 50% the thickness of the laser chip carrier and/or heat sink or the combined thickness of the laser chip carrier and/or heat sink and the active waveguide, for example, in the laser section 101 and/or in the semiconductor waveguide laser. Similar to the discussions above, the length of the isolation section 102 may be at least N times the thickness of the laser chip carrier and/or heat sink 108 or the combined thickness of the laser chip carrier and/or heat sink and the active waveguide, where N is 1, 2, 3, 5, 8, 10, 15, 20, or is a value in any range formed by any of these values or larger or smaller.

In some cases, the waveguide-based optical devices 100, 200, 300, 400A-C, 500, can comprise a semiconductor optical amplifier (SOA), modulator, shutter, attenuator or any combination of these comprising the same or different semiconductor gain material used in the dual-output laser. A wide range of other variations, however, are possible.

In various designs and implementations described above, an isolation section 102 (or 112) may provide both electrical and thermal isolation between a laser section and optical elements of a waveguide-based optical device. In some cases, an isolation layer 107 within the isolation section 102 (or 112) may enhance the level of isolation provided by the isolation section 102 (or 112). While, in some cases, the isolation layer may provide a desired level of electrical isolation, independent of the length of the isolation section 102 (or 112), the desired level of thermal isolation may dependent on the length of the isolation section 102 (or 112). As such, in some examples, the overall length of isolation section 102 (or 112) is determined by a desired level of thermal isolation and can be much larger than a length of the isolation layer therein.

In various implementations, the electrical power, the voltage, or the current applied to the integrated optical element 103 in any of the waveguide-based optical devices described above may comprise a periodic waveform. In some cases, the periodic waveform may have a period between two consecutive on-cycles and/or off-cycles. An on-cycle can be a time interval during which the electric power, magnitude of the voltage, or magnitude of the current, applied to the integrated optical element 103 is larger than a threshold value. An off-cycle can be a time interval during which the electric power, magnitude of the voltage, or magnitude of the current, applied to the integrated optical element 103 is smaller than the threshold value. In some examples, one or both of the on-cycle and the off-cycle can be longer than 1 nanoseconds (ns), 10 ns, 100 ns, 200 ns, 500 ns, 1 microsecond, 10 microseconds or any values in between these values or larger. In some cases, the duration of an off-cycle can be larger than the duration of an off-cycle by a factor of 5, 10, 100, 1000, 10000, or larger. In some examples, duration of the on-cycle or the off-cycle can be from 1% to 10%, from 10% to 20%, from 20% to 30%, from 30% to 40%, from 40% to 50%, from 50% to 60%, from 60% to 70%, from 70% to 80%, from 80% to 90%, or from 90% to 99% the signal or period, or any ranges formed by these values and hence have a duty cycle of these amounts.

In some embodiments, the electrical power, the voltage, or the current applied to the integrated optical element 103 in any of the waveguide-based optical devices described above may comprise an aperiodic time varying signal or an aperiodic waveform. As an example, the integrated optical element 103 may be modulated or switched (e.g., forward or reverse biased) according to signals (e.g., random signals) received from a system, network, or user.

In some examples, one or both on-cycle and the off-cycle of the waveform can be smaller than a time interval during which the SOA 110 provides gain (e.g., a time interval that a voltage or injection current is applied to SOA 110), by a factor of a 10, 100, 1000.

In some implementations, the integrated optical element 103 of the waveguide-based optical devices 100, 200, 300, 400, or 500 comprises a semiconductor optical amplifier that provides a constant or nearly constant optical gain to amplify the laser light generated by the laser section 101 or 120, or further amplify the laser light amplified by the SOA 110. In some such implementations, the isolation section 102 may thermally or electrically isolate the optical element 103 from the OSA 110, laser section 101, or laser region 120, to reduce the impact of the optical amplification in the integrated optical element 103 on the optical gain in the laser section 101 or the SOA 110.

In various implementations, an attenuation, absorption, or amplification of laser light, generated by the laser section 101 of an integrated optical device (e.g., optical device 100, 200, 300, 400, or 500), in the corresponding integrated optical element 103 can be modulated or switched by a periodic waveform (or signal) having a plurality of modulation periods with substantially equal durations. In some examples, a modulation period can be longer than 1 nanoseconds (ns), 10 ns, 100 ns, 200 ns, 500 ns, 1 microsecond, 10 microseconds, or any values in between these values or larger. In some cases, the absorption or amplification of the laser light in the optical element 103 may change by at least 2%, 5%, 10%, 20% (e.g., of a peak value), or larger values, during a modulation period.

In some examples, the amplitude of a voltage or current applied to integrated optical element 103 may change by at least 2%, 5%, 10%, 30%, or 50% of their peak values during a modulation period.

In various implementations, at least one of attenuation, absorption or amplification of laser light, generated by the laser section 101 of an integrated optical device (e.g., integrated optical device 100, 200, 300, 400, or 500), in the corresponding integrated optical element 103 can be modulated or switched by a waveform (e.g., an electric signal). In some cases, the waveform can be periodic. In some cases, the waveform can be aperiodic.

In some cases, the amplification of laser light, generated by the laser region, in the integrated optical element 103 can be modulated by the periodic waveform. In some such cases, the periodic waveform may comprise a modulated current and the integrated optical element 103 can be forward biased during a modulation period.

In some cases, the absorption of laser light, generated by the laser region, in the integrated optical element 103 can be modulated by the periodic waveform. In some such cases, the periodic waveform may comprise a modulated voltage and the integrated optical element 103 can be forward biased during a modulation period.

In some cases, the absorption and the amplification of laser light, generated by the laser region, in the integrated optical element 103 can be modulated by the periodic waveform. In some such cases, the periodic waveform may comprise a modulated voltage during a first portion of the modulation period and a modulated current during a second portion of the modulation period. The integrated optical element is reverse biased during the first portion of the modulation period and forward biased during the second portion of the modulation period.

In some cases, a state of the integrated optical element 103 may change from absorptive to amplifying, or from amplifying to absorptive (e.g., by changing a polarity of a modulating signal to the integrated optical element 103), to modulate light received (input light) from the laser section 101 via the isolation sections 102, 112. For example, when the integrated optical element 103 comprises an SOA, the amplitude of the light transmitted through the SOA can be modulated by modulating the optical gain or optical absorption in the SOA. In some cases, the SOA may amplify light during a first time-interval and absorb light during a second time interval. In some cases, the first and the second time intervals can be different portions of a modulation period. Advantageously, when an SOA amplifies light during a first portion of modulation period and absorbs light during a second portion of the same modulation period, the modulation depth and/or the dynamic range of the resulting modulated light output from the SOA can be greater compared to a case where the SOA (or an electro-absorption modulator) either solely amplifies or solely absorbs light during both the first and second portions of a single modulation period. In some embodiments, a bipolar or four quadrant electrical supply can provide a modulation signal (e.g., a time varying signal) configured to forward bias the SOA, thereby amplify the input light, during the first portion, and reverse bias the SOA, thereby attenuate the input light, during the second portion of the modulation period. Moreover, using an SOA as the integrated optical element 103 for modulating light, may decrease the optical insertion loss associated with optical modulation in the integrated optical element 103.

In some cases, the integrated optical element 103 may include a semiconductor pn junction and a periodic signal having a modulation period may modulate light transmitted through the integrated optical element 103 by changing a bias of the pn junction. In some examples, the signal may forward bias the pn junction during a first portion of the modulation period and reverse bias the pn junction during a second portion of the modulation period. In some cases, a current change across the pn junction may modulate the transmitted light during the first portion of the modulation period and a voltage change across the pn junction may modulate the transmitted light during the second portion of the modulation period.

In some embodiments, the integrated optical device 103 of the waveguide-based optical devices 100, 200, 300, 400A/B/C, and 500 described above may comprise an SOA configured to absorb light during a first portion of a modulation period and amplify light during a second portion of the same modulation period.

In some embodiments, the integrated optical element 103 of a waveguide-based optical device may comprise the same material system, same optical gain layer, the same layered structure or any combination of these as the laser section 101 and/or SOA 110. In some embodiments, the integrated optical element 103 and the laser section 101 and/or SOA 110 of a waveguide-based optical device may comprise at least one common layer (e.g., epitaxial layer). For example, when the integrated optical element 103 of the waveguide-based optical devices 200, 300, 400B, and 400C comprises a second SOA, the integrated optical element 103 and the first SOA 110 may include at least one common layer (e.g., epitaxial layer), comprise the same optical gain material, comprise the same layered structure, or any combination of these. As another example, when the integrated optical element 103 of the waveguide-based optical devices 100 and 400A comprises an SOA, the integrated optical device 103 and the laser section 101 may include at least one common layer, may comprise the same optical gain material, and/or may comprise the same layered structure. In some cases, when the integrated optical element 103 of the waveguide-based optical devices 200, 300, 400B, and 400C comprises a second SOA, the integrated optical element 103 and the first SOA 110 may include at least one common layer, comprise the same optical gain material, and/or the same layered structure or any combination of these. Advantageously, using the same or substantially the same structure (layered structure), composition, or material system, for the integrated optical element 103, the SOA 110, the laser section 101 or any combination of these, simplifies the fabrication process of the corresponding waveguide-based optical device and/or reduces the fabrication cost. In some embodiments, using an SOA as the integrated optical element 103 for modulating light not only increases the dynamic range of the corresponding waveguide-based optical device (or the modulation depth of a modulated optical signal generated by the device), but also enables using the same or substantially the same material composition and/or layered structure at least for SOA 110 and the integrated optical element 103, thereby potentially reducing the fabrication cost and/or complexity of the waveguide based optical device.

In some embodiments, any of the waveguide-based optical devices (e.g., semiconductor chips) described above, e.g., with respect to FIG. 2A/B, 3A/B, or 4B/C, where SOA 110 is disposed between the laser section 101 and the integrated optical element 103, one or both isolation sections 102 and 112 may be eliminated. In these embodiments, the SOA 110 may provide sufficient thermal isolation between the integrated optical element 103 and the laser section 101 to prevent the thermal variation of the integrated optical element 103 (e.g., due to modulation or switching) to cause temporal variation of a characteristic of light emitted by the laser section 101, or otherwise affect a performance of the laser section.

In some embodiments, any of the waveguide-based optical devices (e.g., semiconductor chips) described above, e.g., with respect to FIG. 2A/B, 3A/B, or 4B/C, where SOA 110 is disposed between the laser section 101 and the integrated optical element 103, one or both isolation sections 102 and 112 may be eliminated. In these embodiments, the SOA 110 may provide sufficient thermal isolation between the integrated optical element 103 and the laser section 101 to prevent the thermal variation of the integrated optical element 103 (e.g., due to modulation or switching) to cause temporal variation of a characteristic of light emitted by the laser section 101, or otherwise affect a performance of the laser section.

Likewise, any of the waveguide-based optical devices (e.g., semiconductor chips) described herein, for example, such as those discussed respect to FIG. 2A/B, 3A/B, or 4B/C, where SOA 110 is disposed between the laser section 101 and the integrated optical element 103, may exclude a passive waveguide section between the SOA 110 and the integrated optical element 103 having a thickness such as described herein (e.g., having a length larger than 50% of a semiconductor chip comprising the integrated optical element 103 and the SOA 110). Similarly, any of the waveguide-based optical devices (e.g., semiconductor chips) described herein, for example, with respect to FIG. 2A/B, 3A/B, or 4B/C, where SOA 110 is disposed between the laser section 101 and the integrated optical element 103, may in some implementations, not include or may exclude any passive waveguide section configured to thermally isolate the laser section 101 from the integrated optical element 103. For example, in some embodiments, an end of the integrated optical element(s)103 closer to the laser section 101 may abut an end of the SOA(s) 110 farther from the laser section 101.

### Example Optical System

In some embodiments, an optical system may comprise any of the waveguide-based optical devices (e.g., semiconductor chips) described above with respect to FIG. 1A/B, 2A/B, 3A/B, 4A/B/C, or 5 and an electronic circuit (e.g., an electronic driver) configured to provide a modulation signal (e.g., a time varying signal) to the integrated optical element(s) 103 to modulate or switch light received from the laser section (or region) 101 (e.g., to modulate or switch the amplitude of light). In some cases, the modulation signal or the time varying signal may comprise a waveform. In some cases, the waveform is a periodic waveform. In some cases, the waveform is a aperiodic waveform. In some cases, the electronic circuit can be electrically connected to an electrode of the integrated optical element to apply a voltage on the integrated optical element 103 and/or provide an electric current to the integrated optical element 103. In some cases, the voltage and/or current provided by the electronic circuit may comprise a time varying signal. In some cases, the voltage and/or current provided by the electronic circuit may comprise a time varying component and a constant (e.g., DC) component. In some embodiments, the electronic circuit may comprise a bipolar (or four-quadrant) power supply configured to provide positive and negative output voltages and source and sink an electric current (e.g., the electric current resulting from application of the voltages). In some embodiments, the modulation signal, the time varying signal, or a time varying component of the modulation signal may be configured to forward bias and reverse bias the integrated optical element 103 during different portions of a modulation period. In some cases, the modulation period may comprise a time interval between the beginnings of two immediately subsequent waveforms. In some examples, the modulation signal or a time varying component of the modulation signal can be periodic, and the immediately subsequent waveforms can be substantially identical. In some examples, the modulation signal or a time varying component of the modulation signal can be aperiodic, and the immediately subsequent waveforms can be different. Advantageously, forward biasing and reverse biasing the integrated optical element 103 during a modulation period, by the electronic circuit, increases the modulation depth and/or dynamic range of the resulting modulated optical signal compared to a modulated optical signal generated by either forward biasing (without reverse biasing) or reverse biasing (without forward biasing) the integrated optical element 103 during a modulation period. For example, when the integrated optical element 103 comprises an SOA, which is used to modulate, e.g., the intensity of the transmitted light, during a first portion of the modulation period, the electronic circuit may provide a first time varying voltage that reverse biases the SOA and thereby varies the optical absorption of light through the SOA, and during a second portion of the modulation period the electronic circuit may provide a second time varying voltage that forward biases the SOA and thereby varies the optical amplification of light through the SOA. As such, a difference between the lowest intensity of transmitted light during the first portion of the modulation period and highest intensity of light during the second portion of the modulation period can be large. The modulation depth and/or dynamic range can thereby be increased. Additionally, when the integrated optical element 103 is an SOA that is forward biased during a portion of a modulation period, the insertion optical loss through the integrated optical element 103 may decrease compared to cases where the SOA remains reverse biased during the modulation period or the integrated optical element 103 comprises a non-amplifying optical element such as an electro-optic or an electro-absorption modulator.

In some embodiments, the electronic circuit may receive an initial time varying signal and generate the time varying signal based at least in part on the initial time varying signal. In some cases, the electronic circuit can be a signal conditioning device configured to generate the time varying signal based on the initial time varying signal such that a temporal variation of the time varying signal is proportional to that of the initial time varying signal and the time varying signal is further configured to reverse bias and forward bias the integrated optical element 103 (e.g., an SOA) during a modulation period or cycle. In some embodiments, the electronic circuit may generate the time varying signal without receiving an initial time varying signal.

The modulation signal may comprise a wide range of time varying signals, as described above both periodic and aperiodic. In various implementations, a modulation signal provided to the integrated optical element 103 may comprise an analog or digital signal (e.g., electrical signal). As described herein, in some implementations the integrated optical element 103 comprises a semiconductor optical amplifier (SOA).

In some cases, e.g., when the integrated optical element 103 comprises an SOA, an aperiodic signal may be configured to forward bias the SOA during an ON state and reverse bias the SOA during an OFF state. In some cases, an electrical signal provided to the SOA may be configured to cause the SOA to amplify light received from the laser section 101 to output an optical intensity associated with an ON state and attenuate light received from the laser section 101 to output an optical intensity associated with an OFF state. In some embodiments, the ON state may be associated with a high optical transmission period and OFF state may be associated with a low optical transmission period. In some cases, an ON state may be associated with multiple levels of optical transmission via the integrated optical element 103. For example, during an ON state a modulation signal may change the optical transmission via the integrated optical element 103 from a first value to a second value different from the first value, and then from the second value to a third value different from the first and second values. In some cases, e.g., when the modulation signal comprises a digital signal electrical, ON state can be a first logic state (e.g., 1 or 0) and the OFF state can be a second logic state opposite to the first logic state.

As described above, in some embodiments, an electronic circuit may be provided to generate a time varying signal (e.g., a modulation or switching signal), and provide the time varying signal to the integrated optical element 103 to modulate or switch light received from the laser section 101 (or dual output laser section 120). For example, the electronic circuit may be electrically connected to an electrode for the integrated optical element 103, via an electrical link, and provide the time varying signal to the electrode, via the electrical link, to modulate light transmitted through the integrated optical element 103. The electrode for the integrated optical element 103 may for example, be disposed on, under, in contact with, or otherwise disposed with respect to the integrated optical element 103 to apply electricity or an electrical signal thereto. The electronic circuit may provide the time varying signal to the electrode to modulate or switch intensity or phase of light transmitted through the integrated optical element 103. In some examples, the time varying signal may comprise a waveform. In some examples, the waveform can be periodic or aperiodic. In some embodiments, at least one of optical attenuation, absorption, or amplification of the laser light, generated by the laser section 101 (or dual output laser section 120), in the integrated optical element 103 can be modulated or switched by the waveform. In some embodiments, e.g., when the integrated optical device comprises an SOA, the electronic circuit may be configured to provide positive and negative output voltages to the integrated optical element 103 and sufficiently source and sink the resulting electric currents. In some cases, for example, the electronic circuit may generate a waveform configured to reverse bias and forward bias the integrated optical device 103, e.g., during a modulation period or cycle, or to forward bias the integrated optical device 103 during an ON state and reverse bias the integrated optical device 103 during an OFF state. In some examples, the electronic circuit may comprise a bipolar or four-quadrant power supply. In some examples, the electronic circuit may comprise a printed circuit board (PCB), a field programmable gate array (FPGA), one or more electronic chips, integrated circuits (ICs), etc. In some cases, at least a portion of the electronic circuit may be fabricated on a substrate on which the integrated optical element 103 is fabricated. In various implementations, the portion of the electronic circuit may be co-fabricated or fabricated separately with integrated optical element 103 on the substrate.

### EXAMPLE EMBODIMENTS

Example embodiments described herein have several features, no single one of which is indispensable or solely responsible for their desirable attributes. A variety of example systems and methods are provided below.

### Group-1

Example 1. A waveguide-based optical device extending in a longitudinal direction from a first end to a second end, said waveguide-based optical device comprising:
a semiconductor chip comprising a semiconductor substrate;
a laser region comprising a semiconductor waveguide laser on said semiconductor substrate, said semiconductor chip including said laser region, said laser region comprising an active waveguide portion configured to generate laser light;
an integrated optical element comprising a shutter, attenuator, modulator, amplifier or absorber, said integrated optical element including a waveguide portion for propagation of laser light from said laser, said integrated optical element closer to said second end and said laser region closer to said first end; and
an isolation section comprising a waveguide portion configured to transmit the laser light from the laser region to said integrated optical element, said isolation section between said laser region and said integrated optical element and configured to reduce heat transfer from said integrated optical element to said laser section, said isolation section having a length extending in the longitudinal direction, said isolation section not providing optical gain,
wherein the length of the isolation section is at least 50% of the thickness of the semiconductor chip.

Example 2. The waveguide-based optical device of Example 1, wherein the waveguide portion of said isolation section comprises a material having a bandgap different from that of the active waveguide portion of said laser region.

Example 3. The waveguide-based optical device of Example 1 or 2, wherein the waveguide portion of the isolation section comprises a material having a bandgap different from the waveguide portion of said integrated optical element region.

Example 4. The waveguide-based optical device of any of the Examples above, wherein said isolation section is not configured to receive electrical power or an electrical signal.

Example 5. The waveguide-based optical device of any of the Examples above, wherein a length the isolation section is larger than 50% of the thickness of the active waveguide portion.

Example 6. The waveguide-based optical device of any of the Examples above, wherein the length of the isolation section is at least as large as 50% of the combined thickness of a top cladding layer, a core layer, and a bottom cladding layer of the waveguide laser.

Example 7. The waveguide-based optical device of any of the Examples above, wherein the length of the isolation section is greater than 50% of the thickness of the semiconductor chip.

Example 8. The waveguide-based optical device of any of the Examples above, wherein the length of the isolation section is greater than 50% of a thickness between the top of the active waveguide portion of said laser region to the bottom of the semiconductor chip.

Example 9. The waveguide-based optical device of any of the Examples above, wherein the length of the isolation section is larger than 50% of the thickness between the active waveguide portion of the laser region to the bottom of a substrate on which the waveguide laser is fabricated.

Example 10. The waveguide-based optical device of any of the Examples above, wherein the length of the isolation section is larger than 50% of the combined thickness of the active waveguide portion of the laser region, and any intervening layer between the active waveguide portion of the laser region and a chip carrier on which the semiconductor chip is mounted.

Example 11. The waveguide-based optical device of any of the Examples above, wherein the length of the isolation section is larger than 50% of a thickness of the semiconductor chip and any intervening layer between the semiconductor chip and a chip carrier on which the semiconductor chip is mounted.

Example 12. The waveguide-based optical device of any of the Examples above, wherein the length of the isolation section is larger than the thickness of the active waveguide portion or the laser region.

Example 13. The waveguide-based optical device of any of the Examples above, wherein the length of the isolation section is at least as large as a combined thickness of a top cladding layer, a core layer, and a bottom cladding layer of the waveguide laser.

Example 14. The waveguide-based optical device of any of the Examples above, wherein the length of the isolation section is greater than the thickness of the semiconductor chip.

Example 15. The waveguide-based optical device of any of the Examples above, wherein the length of the isolation section is greater than the thickness between the top of the active waveguide portion of the laser region to the bottom of the semiconductor chip.

Example 16. The waveguide-based optical device of any of the Examples above, wherein the length of the isolation section is larger than the thickness between the active region of the laser region to the bottom of a substrate on which the waveguide laser is fabricated.

Example 17. The waveguide-based optical device of any of the Examples above, wherein the length of the isolation section is larger than the combined thickness of the active waveguide portion of the laser region and any intervening layer between the active waveguide portion of the laser region and a chip carrier on which the semiconductor chip is mounted.

Example 18. The waveguide-based optical device of any of the Examples above, wherein the length of the isolation section is larger than the thickness of the semiconductor chip, and any intervening layer between the semiconductor chip and a chip carrier on which the semiconductor chip is mounted.

Example 19. The waveguide-based optical device of any of the Examples above, wherein said isolation section does not include an electrode configured to apply electrical voltage across said isolation section.

Example 20. The waveguide-based optical device of any of the Examples above, wherein said semiconductor chip includes one or more layers on said semiconductor substrate.

Example 21. The waveguide-based optical device of the Examples above, wherein said semiconductor chip includes one or more semiconductor layers on said semiconductor substrate.

Example 22. The waveguide-based optical device of the Examples above, wherein said laser region includes a plurality of reflectors forming a laser cavity.

Example 23. The waveguide-based optical device of Example 22, wherein at least one of said reflectors comprises a distributed Bragg reflector or a sampled Bragg grating reflector (SG-DBR).

Example 24. The waveguide-based optical device of any of the Examples 1-21, wherein said laser section comprises a distributed feedback (DFB) laser.

Example 25. The waveguide-based optical device of any of the Examples above, wherein said laser region includes one or more electrodes such that electrical power can be applied to at least part of said active waveguide portion of said laser region.

Example 26. The waveguide-based optical device of any of the Examples above, wherein the active waveguide of said laser region comprises III-V semiconductor material.

Example 27. The waveguide-based optical device of any of the Examples above, wherein said integrated optical element includes one or more electrodes configured such that electrical power can be applied to at least part of said waveguide portion of said integrated optical element.

Example 28. The waveguide-based optical device of Example 27, wherein said one or more electrodes are electrically connected to electronics configured to drive said one or more electrodes with a time varying electrical signal.

Example 29. The waveguide-based optical device of any of the Examples above, wherein integrated optical element comprises a shutter or modulator.

Example 30. The waveguide-based optical device of any of the Examples 1-28, wherein integrated optical element comprises an attenuator.

Example 31. The waveguide-based optical device of any of the Examples 1-28, wherein integrated optical element generate heat with application of electricity thereto.

Example 32. The waveguide-based optical device of any of the Examples above, wherein the active waveguide portion of said laser region and the active waveguide portion of said integrated optical element are monolithically fabricated on said semiconductor chip.

Example 33. The waveguide-based optical device of any of the Examples above, further comprising a semiconductor optical amplifier disposed between said laser region and said isolation section, said semiconductor optical amplifier comprising a waveguide portion having optical gain that is configured to propagate laser light from said laser region to said isolation section.

Example 34. The waveguide-based optical device of Example 33, wherein said semiconductor optical amplifier comprises at least one electrode configured such that to provide electrical power to said semiconductor optical amplifier.

Example 35. The waveguide-based optical device of any of the Examples 33 or 34, further comprising an additional isolation section between said laser region and said semiconductor optical amplifier, said additional isolation section comprising a waveguide portion configured to transmit laser light from the active waveguide portion of said laser region to said waveguide portion of semiconductor optical amplifier, said isolation section configured to reduce transfer of heat from said semiconductor optical amplifier to the laser section.

Example 36. The waveguide-based optical device of Example 35, wherein said additional isolation section is not configured to provide optical gain.

Example 37. The waveguide-based optical device of any of the Examples 35 or 36, wherein said waveguide portion of said additional isolation section has a length extending in the longitudinal direction that is at least 50% of the thickness of the semiconductor chip.

Example 38. The waveguide-based optical device of any of the Examples 35-37, wherein the length of the waveguide portion of the additional isolation section is larger than 50% of the thickness of the active waveguide portion.

Example 39. The waveguide-based optical device of any of the Examples 35-38, wherein the length of the waveguide portion of the additional isolation section is at least as large as 50% of the combined thickness of a top cladding layer, a core layer, and a bottom cladding layer of the waveguide laser.

Example 40. The waveguide-based optical device of any of the Examples 35-39, wherein the length of the waveguide portion of the additional isolation section is greater than 50% of the thickness of the semiconductor chip.

Example 41. The waveguide-based optical device of any of the Examples 35-40, wherein the length of the waveguide portion of the additional isolation section is greater than 50% of a thickness between the top of the active waveguide portion of said laser region to the bottom of the semiconductor chip.

Example 42. The waveguide-based optical device of any of the Examples 35-41, wherein the length of the waveguide portion of the additional isolation section is larger than 50% of the thickness between the active waveguide portion of the laser region to the bottom of a substrate on which the waveguide laser is fabricated.

Example 43. The waveguide-based optical device of any of the Examples 35-42, wherein the length of the waveguide portion of the additional isolation section is larger than 50% of the combined thickness of the active waveguide portion of the laser region, and any intervening layer between the active waveguide portion of the laser region and a chip carrier on which the semiconductor chip is mounted.

Example 44. The waveguide-based optical device of any of the Examples 35-43, wherein the length of the waveguide portion of the additional isolation section is larger than 50% of a thickness of the semiconductor chip and any intervening layer between the semiconductor chip and a chip carrier on which the semiconductor chip is mounted.

Example 45. The waveguide-based optical device of any of Example 35 or 36, wherein the length of the waveguide portion of the additional isolation section is larger than 50% of a thickness of a chip carrier or heat sink.

Example 46. The waveguide-based optical device of any the Examples above, wherein said isolation section is not configured to receive electrical power that produces heat.

Example 47. The waveguide-based optical device of any the Examples above, wherein said waveguide portion of said isolation section is not configured to receive electrical power that produces heat.

Example 48. The waveguide-based optical device of any the Examples above, wherein said semiconductor waveguide laser is formed on a semiconductor substrate and said semiconductor substrate is between said semiconductor waveguide laser and a chip carrier or heat sink.

Example 49. The waveguide-based optical device of Example 48, wherein said semiconductor substrate is bonded to said chip carrier or heat sink.

Example 50. The waveguide-based optical device of any the Examples above, wherein said semiconductor waveguide laser is formed on a semiconductor substrate and said semiconductor waveguide laser is between said semiconductor substrate and a chip carrier or heat sink.

Example 51. The waveguide-based optical device of Example 50, wherein said semiconductor substrate has layers formed thereon and at least one of said layers is bonded to said carrier or heat sink.

Example 52. The waveguide-based optical device of any of the Examples 48-51, wherein said semiconductor waveguide laser comprises semiconductor layers epitaxially grown on said semiconductor substrate.

Example 53. The waveguide-based optical device of any Examples above, wherein said chip carrier or heat sink comprises metal.

Example 54. The waveguide-based optical device of Example 48, wherein the length of the waveguide portion of the isolation section is larger than 50% of a thickness of the chip carrier or heat sink.

Example 55. The waveguide-based optical device of any of the Examples above, wherein said semiconductor waveguide laser comprises a dual output laser having first and second output ports of said active waveguide on opposite first and second sides of said semiconductor waveguide laser that each output laser light.

Example 56. The waveguide-based optical device of Example 55, wherein said waveguide portion of said integrated optical element is optically coupled to receive laser light from said first output port of said dual output laser.

Example 57. The waveguide-based optical device of Example 56, wherein said waveguide portion of said isolation section is optically coupled to receive laser light from said first output port of said dual output laser and to transmit said laser light to said waveguide portion of said integrated optical element.

Example 58. The waveguide-based optical device of any of the Examples above, wherein a waveguide portion of an additional integrated optical element is optically coupled to receive laser light from said second output port of said dual output laser.

Example 59. The waveguide-based optical device of any of the Examples above, further comprising an additional isolation section having a waveguide portion that is optically coupled to receive laser light from said second output port of said dual output laser and transmit said laser light to said waveguide portion of said additional optical element.

Example 60. The waveguide-based optical device of any of the Examples above, wherein said waveguide portion of said isolation section comprises has a constant cross section size and shape.

Example 61. The waveguide-based optical device of any of the Examples above, wherein said waveguide portion of said isolation section comprises has a constant index of refraction along the length thereof.

Example 62. The waveguide-based optical device of any of the Examples above, wherein at least one of optical attenuation, absorption or amplification of the laser light, generated by the laser region, in the integrated optical element is modulated or switched by a periodic waveform comprising a plurality of modulation periods.

Example 63. The waveguide-based optical device of Example 62, wherein the modulation period is longer than 100 nanoseconds.

Example 64. The waveguide-based optical device of Example 62, wherein the modulation period is shorter than a time interval during which the laser light is generated by the laser region.

Example 65. The waveguide-based optical device of Example 62, wherein the optical absorption or amplification of the laser light output from the integrated optical element changes by at least 5% during a modulation period.

Example 66. The waveguide-based optical device of any of the Examples 1-61, wherein a voltage or a current applied to the integrated optical element is modulated by a periodic waveform comprising a plurality of modulation periods.

Example 67. The waveguide-based optical device of Example 66, wherein the modulation period is longer than 100 nanoseconds.

Example 68. The waveguide-based optical device of Example 66, wherein the modulation period is shorter than a time interval during which the laser light is generated by the laser region.

Example 69. The waveguide-based optical device of Example 66, wherein the amplitude of the voltage or current applied to the integrated optical element changes by at least 5% of its peak value during a modulation period.

Example 70. The waveguide-based optical device of any of the Examples above, wherein amplification of the laser light, generated by the laser region, in the integrated optical element is modulated by a periodic waveform comprising a plurality of modulation periods.

Example 71. The waveguide-based optical device of Example 70, wherein periodic waveform comprises a modulated current and the integrated optical element is forward biased during a modulation period.

Example 72. The waveguide-based optical device of any of the Examples 1-61, wherein absorption of the laser light, generated by the laser region, in the integrated optical element is modulated by a periodic waveform comprising a plurality of modulation periods.

Example 73. The waveguide-based optical device of Example 72, wherein periodic waveform comprises a modulated voltage and the integrated optical element is reverse biased during a modulation period.

Example 74. The waveguide-based optical device of any of the Examples 1-61, wherein absorption and the amplification of the laser light, generated by the laser region, in the integrated optical element are modulated by a periodic waveform comprising a plurality of modulation periods.

Example 75. The waveguide-based optical device of Example 74, wherein the periodic waveform comprises a modulated voltage during a first portion of a modulation period and comprises a modulated current during a second portion of the modulation period, the integrated optical element is reverse biased during the first portion of the modulation period, and forward biased during the second portion of the modulation period.

Example 76. The waveguide-based optical device of any of the Examples above, wherein the isolation section does not alter a polarization of light transmitted therethrough.

Example 77. The waveguide-based optical device of Example 76, wherein the isolation section does not alter a spectrum of light transmitted therethrough.

Example 78. The waveguide-based optical device of Example 77, wherein the isolation section does not comprise a grating.

Example 79. The waveguide-based optical device of any of the Examples above, wherein the isolation section does not comprise a beam splitter.

Example 80. The waveguide-based optical device of any of the Examples above, wherein the isolation section does not comprise a multiplexer or coupler.

Example 81. The waveguide-based optical device of any of the Examples above, wherein the isolation section does not comprise a mode converter.

Example 82. The waveguide-based optical device of any of the Examples above, wherein the isolation section attenuates light transmitted therethrough by less than 2%.

Example 83. The waveguide-based optical device of any of the Examples above, wherein at least one of optical attenuation, absorption or amplification of the laser light, generated by the laser region, in the integrated optical element is modulated or switched by an aperiodic waveform.

Example 84. The waveguide-based optical device of Example 83, wherein the optical attenuation, absorption or amplification of the laser light output from the integrated optical element changes by at least 5%.

Example 85. The waveguide-based optical device of any of the Examples 83-84, wherein the amplitude of a voltage or current applied to the integrated optical element changes by at least 5% of its peak value.

Example 86. The waveguide-based optical device of any of the Examples 83-85, wherein the aperiodic waveform is configured to forward bias the integrated optical element.

Example 87. The waveguide-based optical device of any of the Examples 83-85, wherein the aperiodic waveform is configured to reverse bias the integrated optical element.

Example 88. The waveguide-based optical device of any of the Examples 83-85, wherein the aperiodic waveform is configured to forward bias and reverse bias the integrated optical element.

Example 89. The waveguide-based optical device of Example 88, wherein the aperiodic waveform is configured to forward bias the integrated optical element during an ON state and reverse bias the SOA during an OFF state.

Example 90. The waveguide-based optical device of any of the Examples above, wherein at least one of optical attenuation, absorption or amplification of the laser light, generated by the laser region, in the integrated optical element is modulated or switched by a periodic waveform.

Group-2 Semiconductor Optical Amplifier (between Integrated Optical Element and Laser Region)

Example 1. A waveguide-based optical device extending in a longitudinal direction from a first end to a second end, said waveguide-based optical device comprising:
a semiconductor chip comprising a semiconductor substrate;
a laser region comprising a semiconductor waveguide laser on said semiconductor substrate, said semiconductor chip including said laser region, said laser region comprising an active waveguide portion configured to generate laser light;
an integrated optical element including a waveguide portion for propagation of laser light from said laser, said integrated optical element closer to said second end and said laser region closer to said first end; and
an isolation section comprising a waveguide portion configured to transmit the laser light from the laser region to said integrated optical element, said isolation section between said laser region and said integrated optical element and configured to reduce heat transfer from said integrated optical element to said laser section, said isolation section having a length extending in the longitudinal direction, said isolation section not providing optical gain,
a semiconductor optical amplifier disposed between said laser region and said isolation section, said semiconductor optical amplifier comprising a waveguide having optical gain that is configured to propagate laser light from said laser region to said isolation section.

Example 2. The waveguide-based optical device of Example 1, wherein said semiconductor optical amplifier comprises at least one electrode configured to provide electrical power to said semiconductor optical amplifier.

Example 3. The waveguide-based optical device of any of the Examples 1 or 2, further comprising an additional isolation section between said laser region and said semiconductor optical amplifier, said additional isolation section comprising a waveguide portion configured to transmit laser light from the laser region to said semiconductor optical amplifier, said isolation section configured to reduce heat transfer from said semiconductor optical amplifier to said laser region.

Example 4. The waveguide-based optical device of Example 3, wherein said additional isolation section does not provide optical gain.

Example 5. The waveguide-based optical device of any of the Examples above, wherein integrated optical element comprises a shutter or modulator.

Example 6. The waveguide-based optical device of any of Example 1-4, wherein integrated optical element comprises an attenuator.

Example 7. The waveguide-based optical device of any of Example 1-4, wherein integrated optical element comprises a semiconductor optical amplifier.

Example 8. The waveguide-based optical device of any of the Examples above, wherein optical absorption or amplification of the laser light, generated by the laser region, in the integrated optical element is modulated by a periodic waveform comprising a plurality of modulation periods.

Example 9. The waveguide-based optical device of Example 8, wherein the modulation period is longer than 100 nanoseconds.

Example 10. The waveguide-based optical device of Example 8, wherein the modulation period is shorter than a time interval during which the laser light is generated by the laser region.

Example 11. The waveguide-based optical device of Example 8, wherein the optical attenuation, absorption or amplification of the laser light output from the integrated optical element changes by at least 5% during a modulation period.

Example 12. The waveguide-based optical device of any of the Examples 1-7, wherein a voltage or a current applied to the integrated optical element is modulated by a periodic waveform comprising a plurality of modulation periods.

Example 13. The waveguide-based optical device of Example 12, wherein the modulation period is longer than 100 nanoseconds.

Example 14. The waveguide-based optical device of Example 12, wherein the modulation period is shorter than a time interval during which the laser light is generated by the laser region.

Example 15. The waveguide-based optical device of Example 12, wherein the amplitude of the voltage or current applied to the integrated optical element changes by at least 5% of its peak value during a modulation period.

Example 16. The waveguide-based optical device of any of the Examples above, wherein amplification of the laser light, generated by the laser region, in the integrated optical element is modulated by a periodic waveform comprising a plurality of modulation periods.

Example 17. The waveguide-based optical device of Example 16, wherein periodic waveform comprises a modulated current and the integrated optical element is forward biased during a modulation period.

Example 18. The waveguide-based optical device of any of the Examples 1-7, wherein absorption of the laser light, generated by the laser region, in the integrated optical element is modulated by a periodic waveform comprising a plurality of modulation periods.

Example 19. The waveguide-based optical device of Example 18, wherein periodic waveform comprises a modulated voltage and the integrated optical element is reverse biased during a modulation period.

Example 20. The waveguide-based optical device of any of the Examples 1-7, wherein absorption and the amplification of the laser light, generated by the laser region, in the integrated optical element are modulated by a periodic waveform comprising a plurality of modulation periods.

Example 21. The waveguide-based optical device of Example 20, wherein the periodic waveform comprises a modulated voltage during a first portion of a modulation period and comprises a modulated current during a second portion of the modulation period, the integrated optical element is reverse biased during the first portion of the modulation period, and forward biased during the second portion of the modulation period.

Example 22. The waveguide-based optical device of any of the Examples above, wherein the isolation section does not alter a polarization of light transmitted therethrough.

Example 23. The waveguide-based optical device of Example 22, wherein the isolation section does not alter a spectrum of light transmitted therethrough.

Example 24. The waveguide-based optical device of Example 23, wherein the isolation section does not comprise a grating.

Example 25. The waveguide-based optical device of any of the Examples above, wherein the isolation section does not comprise a beam splitter.

Example 26. The waveguide-based optical device of any of the Examples above, wherein the isolation section does not comprise a multiplexer or coupler.

Example 27. The waveguide-based optical device of any of the Examples above, wherein the isolation section does not comprise a mode converter.

Example 28. The waveguide-based optical device of any of the Examples above, wherein the isolation section attenuates light transmitted therethrough by less than 2%.

Example 29. The waveguide-based optical device of any of the Examples above, wherein at least one of optical attenuation, absorption or amplification of the laser light, generated by the laser region, in the integrated optical element is modulated by an aperiodic waveform.

Example 30. The waveguide-based optical device of Example 29, wherein the optical attenuation, absorption or amplification of the laser light output from the integrated optical element changes by at least 5%.

Example 31. The waveguide-based optical device of any of the Examples 29-30, wherein the amplitude of a voltage or current applied to the integrated optical element changes by at least 5% of its peak value.

Example 32. The waveguide-based optical device of any of the Examples 29-30, wherein the aperiodic waveform is configured to forward bias the integrated optical element.

Example 33. The waveguide-based optical device of any of the Examples 29-30, wherein the aperiodic waveform is configured to reverse bias the integrated optical element.

Example 34. The waveguide-based optical device of any of the Examples 29-30, wherein the aperiodic waveform is configured to forward bias and reverse bias the integrated optical element.

Example 35. The waveguide-based optical device of Example 34, wherein the aperiodic waveform is configured to forward bias the integrated optical element during an ON state and reverse bias the SOA during an OFF state.

Example 36. The waveguide-based optical device of any of the Examples above, wherein at least one of optical attenuation, absorption or amplification of the laser light, generated by the laser region, in the integrated optical element is modulated or switched by a periodic waveform.

### Group-3: Dual Output Laser

Example 1. A waveguide-based optical device extending in a longitudinal direction from a first end to a second end, said waveguide-based optical device comprising:
a semiconductor chip comprising a semiconductor substrate;
a laser region comprising a dual output semiconductor waveguide laser on said semiconductor substrate, said semiconductor chip including said laser region, said laser region comprising an active waveguide portion configured to generate laser light, said dual output semiconductor waveguide laser having first and second output ports of said active waveguide on opposite first and second sides of said dual output semiconductor waveguide laser that each output laser light;
an integrated optical element including a waveguide portion for propagation of laser light from said laser, said waveguide portion of said integrated optical element optically coupled to receive laser light from said first output port of said dual output semiconductor waveguide laser; and
an isolation section comprising a waveguide portion optically coupled to receive laser light from said first output port of said dual output laser and configured to transmit said laser light to said waveguide portion of said integrated optical element, said isolation section between said laser region and said integrated optical element and configured to reduce heat transfer from said integrated optical element to said laser section, said isolation section having a length extending in the longitudinal direction, said isolation section not providing optical gain.

Example 2. The waveguide-based optical device of Example 1, further comprising an additional integrated optical element having a waveguide portion that is optically coupled to receive laser light from said second output port of said dual output laser.

Example 3. The waveguide-based optical device of Example 2, further comprising an additional isolation section having a waveguide portion that is optically coupled to receive laser light from said second output port of said dual output laser and transmit said laser light to said waveguide portion of said additional optical element.

Example 4. The waveguide-based optical device of any of the Examples above, wherein optical absorption or amplification of the laser light, generated by the laser region, in the integrated optical element is modulated by a periodic waveform comprising a plurality of modulation periods.

Example 5. The waveguide-based optical device of Example 4, wherein the modulation period is longer than 100 nanoseconds.

Example 6. The waveguide-based optical device of Example 4, wherein the modulation period is shorter than a time interval during which the laser light is generated by the laser region.

Example 7. The waveguide-based optical device of Example 4, wherein the optical absorption or amplification of the laser light output from the integrated optical element changes by at least 5% during a modulation period.

Example 8. The waveguide-based optical device of any of the Examples 1-3, wherein a voltage or a current applied to the integrated optical element is modulated by a periodic waveform comprising a plurality of modulation periods.

Example 9. The waveguide-based optical device of Example 8, wherein the modulation period is longer than 100 nanoseconds.

Example 10. The waveguide-based optical device of Example 8, wherein the modulation period is shorter than a time interval during which the laser light is generated by the laser region.

Example 11. The waveguide-based optical device of Example 8, wherein the amplitude of the voltage or current applied to the integrated optical element changes by at least 5% of its peak value during a modulation period.

Example 12. The waveguide-based optical device of any of the Examples above, wherein amplification of the laser light, generated by the laser region, in the integrated optical element is modulated by a periodic waveform comprising a plurality of modulation periods.

Example 13. The waveguide-based optical device of Example 12, wherein periodic waveform comprises a modulated current and the integrated optical element is forward biased during a modulation period.

Example 14. The waveguide-based optical device of any of the Examples 1-3, wherein absorption of the laser light, generated by the laser region, in the integrated optical element is modulated by a periodic waveform comprising a plurality of modulation periods.

Example 15. The waveguide-based optical device of Example 14, wherein periodic waveform comprises a modulated voltage and the integrated optical element is reverse biased during a modulation period.

Example 16. The waveguide-based optical device of any of the Examples 1-3, wherein absorption and the amplification of the laser light, generated by the laser region, in the integrated optical element are modulated by a periodic waveform comprising a plurality of modulation periods.

Example 17. The waveguide-based optical device of Example 16, wherein the periodic waveform comprises a modulated voltage during a first portion of a modulation period and comprises a modulated current during a second portion of the modulation period, the integrated optical element is reverse biased during the first portion of the modulation period, and forward biased during the second portion of the modulation period.

Example 18. The waveguide-based optical device of any of the Examples above, wherein the isolation section does not alter a polarization of light transmitted therethrough.

Example 19. The waveguide-based optical device of Example 18, wherein the isolation section does not alter a spectrum of light transmitted therethrough.

Example 20. The waveguide-based optical device of Example 19, wherein the isolation section does not comprise a grating.

Example 21. The waveguide-based optical device of any of the Examples above, wherein the isolation section does not comprise a beam splitter.

Example 22. The waveguide-based optical device of any of the Examples above, wherein the isolation section does not comprise a multiplexer or coupler.

Example 23. The waveguide-based optical device of any of the Examples above, wherein the isolation section does not comprise a mode converter.

Example 24. The waveguide-based optical device of any of the Examples above, wherein the isolation section attenuates light transmitted therethrough by less than 2%.

Example 25. The waveguide-based optical device of any of the Examples above, wherein at least one of optical attenuation, absorption or amplification of the laser light, generated by the laser region, in the integrated optical element is modulated or switched by an aperiodic waveform.

Example 26. The waveguide-based optical device of Example 25, wherein the optical attenuation, absorption or amplification of the laser light output from the integrated optical element changes by at least 5%.

Example 27. The waveguide-based optical device of any of the Examples 25-26, wherein the amplitude of a voltage or current applied to the integrated optical element changes by at least 5% of its peak value.

Example 28. The waveguide-based optical device of any of the Examples 25-27, wherein the aperiodic waveform is configured to forward bias the integrated optical element.

Example 29. The waveguide-based optical device of any of the Examples 25-27, wherein the aperiodic waveform is configured to reverse bias the integrated optical element.

Example 30. The waveguide-based optical device of any of the Examples 25-27, wherein the aperiodic waveform is configured to forward bias and reverse bias the integrated optical element.

Example 31. The waveguide-based optical device of Example 30, wherein the aperiodic waveform is configured to forward bias the integrated optical element during an ON state and reverse bias the SOA during an OFF state.

Example 32. The waveguide-based optical device of any of the Examples above, wherein at least one of optical attenuation, absorption or amplification of the laser light, generated by the laser region, in the integrated optical element is modulated or switched by a periodic waveform.

### Group-4: Isolation Layer

Example 1. A waveguide-based optical device extending in a longitudinal direction from a first end to a second end, said waveguide-based optical device comprising:
a semiconductor chip comprising a semiconductor substrate;
a laser region comprising a semiconductor waveguide laser on said semiconductor substrate, said semiconductor chip including said laser region, said laser region comprising an active waveguide portion configured to generate laser light;
an integrated optical element including a waveguide portion for propagation of laser light from said laser, said integrated optical element closer to said second end and said laser region closer to said first end; and
an isolation section comprising a waveguide portion configured to transmit the laser light from the laser region to said integrated optical element, said isolation section between said laser region and said integrated optical element, said isolation section comprising an isolation section having reduce thermal conductivity such that thermal heat transfer from said integrated optical element to said laser section is reduced, said isolation section not providing optical gain.

Example 2. The waveguide-based optical device of Example 1, wherein said isolation section has a thermal conductivity that is lower than other portions of said isolation section.

Example 3. The waveguide-based optical device of Example 1 or 2, wherein said isolation section has a thermal conductivity that is lower than at least a portion of said integrated optical element.

Example 4. The waveguide-based optical device of any of the Examples 1-3, wherein said isolation section has a thermal conductivity that is lower than at least a portion of said laser region.

Example 5. The waveguide-based optical device of any of the Examples above, wherein optical absorption or amplification of the laser light, generated by the laser region, in the integrated optical element is modulated by a periodic waveform comprising a plurality of modulation periods.

Example 6. The waveguide-based optical device of Example 5, wherein the modulation period is longer than 100 nanoseconds.

Example 7. The waveguide-based optical device of Example 5, wherein the modulation period is shorter than a time interval during which the laser light is generated by the laser region.

Example 8. The waveguide-based optical device of Example 5, wherein the optical absorption or amplification of the laser light output from the integrated optical element changes by at least 5% during a modulation period.

Example 9. The waveguide-based optical device of any of the Examples 1-4, wherein a voltage or a current applied to the integrated optical element is modulated by a periodic waveform comprising a plurality of modulation periods.

Example 10. The waveguide-based optical device of Example 9, wherein the modulation period is longer than 100 nanoseconds.

Example 11. The waveguide-based optical device of Example 9, wherein the modulation period is shorter than a time interval during which the laser light is generated by the laser region.

Example 12. The waveguide-based optical device of Example 9, wherein the amplitude of the voltage or current applied to the integrated optical element changes by at least 5% of its peak value during a modulation period.

Example 13. The waveguide-based optical device of any of the Examples above, wherein amplification of the laser light, generated by the laser region, in the integrated optical element is modulated by a periodic waveform comprising a plurality of modulation periods.

Example 14. The waveguide-based optical device of Example 13, wherein periodic waveform comprises a modulated current and the integrated optical element is forward biased during a modulation period.

Example 15. The waveguide-based optical device of any of the Examples 1-4, wherein absorption of the laser light, generated by the laser region, in the integrated optical element is modulated by a periodic waveform comprising a plurality of modulation periods.

Example 16. The waveguide-based optical device of Example 15, wherein periodic waveform comprises a modulated voltage and the integrated optical element is reverse biased during a modulation period.

Example 17. The waveguide-based optical device of any of the Examples 1-4, wherein absorption and the amplification of the laser light, generated by the laser region, in the integrated optical element are modulated by a periodic waveform comprising a plurality of modulation periods.

Example 18. The waveguide-based optical device of Example 17, wherein the periodic waveform comprises a modulated voltage during a first portion of a modulation period and comprises a modulated current during a second portion of the modulation period, the integrated optical element is reverse biased during the first portion of the modulation period, and forward biased during the second portion of the modulation period.

Example 19. The waveguide-based optical device of any of the Examples above, wherein the isolation section does not alter a polarization of light transmitted therethrough.

Example 20. The waveguide-based optical device of Example 19, wherein the isolation section does not alter a spectrum of light transmitted therethrough.

Example 21. The waveguide-based optical device of Example 20, wherein the isolation section does not comprise a grating.

Example 22. The waveguide-based optical device of any of the Examples above, wherein the isolation section does not comprise a beam splitter.

Example 23. The waveguide-based optical device of any of the Examples above, wherein the isolation section does not comprise a multiplexer or coupler.

Example 24. The waveguide-based optical device of any of the Examples above, wherein the isolation section does not comprise a mode converter.

Example 25. The waveguide-based optical device of any of the Examples above, wherein the isolation section attenuates light transmitted therethrough by less than 2%.

Example 26. The waveguide-based optical device of any of the Examples above, wherein at least one of optical attenuation, absorption or amplification of the laser light, generated by the laser region, in the integrated optical element is modulated by an aperiodic waveform.

Example 27. The waveguide-based optical device of Example 26, wherein at least one of the optical attenuation, absorption or amplification of the laser light output from the integrated optical element changes by at least 5%.

Example 28. The waveguide-based optical device of any of the Examples 26-27, wherein the amplitude of a voltage or current applied to the integrated optical element changes by at least 5% of its peak value.

Example 29. The waveguide-based optical device of any of the Examples 26-28, wherein the aperiodic waveform is configured to forward bias the integrated optical element.

Example 30. The waveguide-based optical device of any of the Examples 26-28, wherein the aperiodic waveform is configured to reverse bias the integrated optical element.

Example 31. The waveguide-based optical device of any of the Examples 26-28, wherein the aperiodic waveform is configured to forward bias and reverse bias the integrated optical element.

Example 32. The waveguide-based optical device of Example 31, wherein the aperiodic waveform is configured to forward bias the integrated optical element during an ON state and reverse bias the SOA during an OFF state.

Example 32. The waveguide-based optical device of any of the Examples above, wherein at least one of optical attenuation, absorption or amplification of the laser light, generated by the laser region, in the integrated optical element is modulated or switched by a periodic waveform.

Group-5: Waveguide-Based Optical Device with an SOA

Example 1. A waveguide-based optical device extending in a longitudinal direction from a first end to a second end, said waveguide-based optical device comprising:
a semiconductor chip comprising a semiconductor substrate;
a laser region comprising a semiconductor waveguide laser on said semiconductor substrate, said semiconductor chip including said laser region, said laser region comprising an active waveguide portion configured to generate laser light;
a first semiconductor optical amplifier (SOA1) including a waveguide portion for propagation of laser light from said laser, said SOA1 closer to said second end and said laser region closer to said first end; and
an isolation section comprising a waveguide portion configured to transmit the laser light from the laser region to said SOA1, said isolation section between said laser region and said SOA1 configured to reduce heat transfer from said SOA1 to said laser section, said isolation section having a length extending in the longitudinal direction, said isolation section not providing optical gain,
wherein the length of the isolation section is at least 50% of the thickness of the semiconductor chip.

Example 2. The waveguide-based optical device of Example 1, wherein the waveguide portion of said isolation section comprises a material having a bandgap different from that of the active waveguide portion of said laser region.

Example 3. The waveguide-based optical device of Example 1 or 2, wherein the waveguide portion of the isolation section comprises a material having a bandgap different from the waveguide portion of said SOA1.

Example 4. The waveguide-based optical device of any of the Examples above, wherein said isolation section is not configured to receive electrical power or an electrical signal.

Example 5. The waveguide-based optical device of any of the Examples above, wherein a length the isolation section is larger than 50% of the thickness of the active waveguide portion.

Example 6. The waveguide-based optical device of any of the Examples above, wherein the length of the isolation section is at least as large as 50% of the combined thickness of a top cladding layer, a core layer, and a bottom cladding layer of the waveguide laser.

Example 7. The waveguide-based optical device of any of the Examples above, wherein the length of the isolation section is greater than 50% of the thickness of the semiconductor chip.

Example 8. The waveguide-based optical device of any of the Examples above, wherein the length of the isolation section is greater than 50% of a thickness between the top of the active waveguide portion of said laser region to the bottom of the semiconductor chip.

Example 9. The waveguide-based optical device of any of the Examples above, wherein the length of the isolation section is larger than 50% of the thickness between the active waveguide portion of the laser region to the bottom of a substrate on which the waveguide laser is fabricated.

Example 10. The waveguide-based optical device of any of the Examples above, wherein the length of the isolation section is larger than 50% of the combined thickness of the active waveguide portion of the laser region, and any intervening layer between the active waveguide portion of the laser region and a chip carrier on which the semiconductor chip is mounted.

Example 11. The waveguide-based optical device of any of the Examples above, wherein the length of the isolation section is larger than 50% of a thickness of the semiconductor chip and any intervening layer between the semiconductor chip and a chip carrier on which the semiconductor chip is mounted.

Example 12. The waveguide-based optical device of any of the Examples above, wherein the length of the isolation section is larger than the thickness of the active waveguide portion or the laser region.

Example 13. The waveguide-based optical device of any of the Examples above, wherein the length of the isolation section is at least as large as a combined thickness of a top cladding layer, a core layer, and a bottom cladding layer of the waveguide laser.

Example 14. The waveguide-based optical device of any of the Examples above, wherein the length of the isolation section is greater than the thickness of the semiconductor chip.

Example 15. The waveguide-based optical device of any of the Examples above, wherein the length of the isolation section is greater than the thickness between the top of the active waveguide portion of the laser region to the bottom of the semiconductor chip.

Example 16. The waveguide-based optical device of any of the Examples above, wherein the length of the isolation section is larger than the thickness between the active region of the laser region to the bottom of a substrate on which the waveguide laser is fabricated.

Example 17. The waveguide-based optical device of any of the Examples above, wherein the length of the isolation section is larger than the combined thickness of the active waveguide portion of the laser region and any intervening layer between the active waveguide portion of the laser region and a chip carrier on which the semiconductor chip is mounted.

Example 18. The waveguide-based optical device of any of the Examples above, wherein the length of the isolation section is larger than the thickness of the semiconductor chip, and any intervening layer between the semiconductor chip and a chip carrier on which the semiconductor chip is mounted.

Example 19. The waveguide-based optical device of any of the Examples above, wherein said isolation section does not include an electrode configured to apply electrical voltage across said isolation section.

Example 20. The waveguide-based optical device of any of the Examples above, wherein said semiconductor chip includes one or more layers on said semiconductor substrate.

Example 21. The waveguide-based optical device of the Examples above, wherein said semiconductor chip includes one or more semiconductor layers on said semiconductor substrate.

Example 22. The waveguide-based optical device of the Examples above, wherein said laser region includes a plurality of reflectors forming a laser cavity.

Example 23. The waveguide-based optical device of Example 22, wherein at least one of said reflectors comprises a distributed Bragg reflector or a sampled Bragg grating reflector (SG-DBR).

Example 24. The waveguide-based optical device of any of the Examples 1-21, wherein said laser section comprises a distributed feedback (DFB) laser.

Example 25. The waveguide-based optical device of any of the Examples above, wherein said laser region includes one or more electrodes such that electrical power can be applied to at least part of said active waveguide portion of said laser region.

Example 26. The waveguide-based optical device of any of the Examples above, wherein the active waveguide of said laser region comprises III-V semiconductor material.

Example 27. The waveguide-based optical device of any of the Examples above, wherein said SOA1 includes one or more electrodes configured such that a modulation signal can be applied to at least part of said waveguide portion of said SOA1.

Example 28. The waveguide-based optical device of Example 27, wherein said one or more electrodes are electrically connected to electronics configured to drive said one or more electrodes with a time varying electrical signal.

Example 29. The waveguide-based optical device of any of the Examples above, wherein the active waveguide portion of said laser region and the active waveguide portion of said SOA1 are monolithically fabricated on said semiconductor chip.

Example 30. The waveguide-based optical device of Example 29, wherein the active waveguide portion of said laser region and the active waveguide portion of said SOA1 comprise the same composition, same layered structure, or at least one common layer.

Example 31. The waveguide-based optical device of any of the Examples above, further comprising a second semiconductor optical amplifier (SOA2) disposed between said laser region and said isolation section, said SOA2 comprising a waveguide portion having optical gain that is configured to propagate laser light from said laser region to said isolation section.

Example 32. The waveguide-based optical device of Example 31, wherein the active waveguide portion of said laser region and an active waveguide portion of said SOA2 comprise the same composition, layered structure, or at least one common layer.

Example 33. The waveguide-based optical device of Example 31, wherein the active waveguide portion of said SOA1 and an active waveguide portion of said SOA2 comprise the same composition, layered structure, or at least one common layer.

Example 34. The waveguide-based optical device of any of Example 31, wherein said SOA2 comprises at least one electrode configured such that to provide electrical power to said SOA2.

Example 35. The waveguide-based optical device of any of the Examples 31 or 34, further comprising an additional isolation section between said laser region and said SOA2, said additional isolation section comprising a waveguide portion configured to transmit laser light from the active waveguide portion of said laser region to said waveguide portion of said SOA2, said isolation section configured to reduce transfer of heat from said semiconductor optical amplifier to the laser section.

Example 36. The waveguide-based optical device of Example 35, wherein said additional isolation section is not configured to provide optical gain.

Example 37. The waveguide-based optical device of any of the Examples 35 or 36, wherein said waveguide portion of said additional isolation section has a length extending in the longitudinal direction that is at least 50% of the thickness of the semiconductor chip.

Example 38. The waveguide-based optical device of any of the Examples 35-37, wherein the length of the waveguide portion of the additional isolation section is larger than 50% of the thickness of the active waveguide portion.

Example 39. The waveguide-based optical device of any of the Examples 35-38, wherein the length of the waveguide portion of the additional isolation section is at least as large as 50% of the combined thickness of a top cladding layer, a core layer, and a bottom cladding layer of the waveguide laser.

Example 40. The waveguide-based optical device of any of the Examples 35-39, wherein the length of the waveguide portion of the additional isolation section is greater than 50% of the thickness of the semiconductor chip.

Example 41. The waveguide-based optical device of any of the Examples 35-40, wherein the length of the waveguide portion of the additional isolation section is greater than 50% of a thickness between the top of the active waveguide portion of said laser region to the bottom of the semiconductor chip.

Example 42. The waveguide-based optical device of any of the Examples 35-41, wherein the length of the waveguide portion of the additional isolation section is larger than 50% of the thickness between the active waveguide portion of the laser region to the bottom of a substrate on which the waveguide laser is fabricated.

Example 43. The waveguide-based optical device of any of the Examples 35-42, wherein the length of the waveguide portion of the additional isolation section is larger than 50% of the combined thickness of the active waveguide portion of the laser region, and any intervening layer between the active waveguide portion of the laser region and a chip carrier on which the semiconductor chip is mounted.

Example 44. The waveguide-based optical device of any of the Examples 35-43, wherein the length of the waveguide portion of the additional isolation section is larger than 50% of a thickness of the semiconductor chip and any intervening layer between the semiconductor chip and a chip carrier on which the semiconductor chip is mounted.

Example 45. The waveguide-based optical device of any of Example 35 or 36, wherein the length of the waveguide portion of the additional isolation section is larger than 50% of a thickness of a chip carrier or heat sink.

Example 46. The waveguide-based optical device of any the Examples above, wherein said isolation section is not configured to receive electrical power that produces heat.

Example 47. The waveguide-based optical device of any the Examples above, wherein said waveguide portion of said isolation section is not configured to receive electrical power that produces heat.

Example 48. The waveguide-based optical device of any the Examples above, wherein said semiconductor waveguide laser is formed on a semiconductor substrate and said semiconductor substrate is between said semiconductor waveguide laser and a chip carrier or heat sink.

Example 49. The waveguide-based optical device of Example 48, wherein said semiconductor substrate is bonded to said chip carrier or heat sink.

Example 50. The waveguide-based optical device of any the Examples above, wherein said semiconductor waveguide laser is formed on a semiconductor substrate and said semiconductor waveguide laser is between said semiconductor substrate and a chip carrier or heat sink.

Example 51. The waveguide-based optical device of Example 50, wherein said semiconductor substrate has layers formed thereon and at least one of said layers is bonded to said carrier or heat sink.

Example 52. The waveguide-based optical device of any of the Examples 48-51, wherein said semiconductor waveguide laser comprises semiconductor layers epitaxially grown on said semiconductor substrate.

Example 53. The waveguide-based optical device of any the Examples above, wherein said chip carrier or heat sink comprises metal.

Example 54. The waveguide-based optical device of any of Example 48, wherein the length of the waveguide portion of the isolation section is larger than 50% of a thickness of the chip carrier or heat sink.

Example 55. The waveguide-based optical device of any of the Examples above, wherein said semiconductor waveguide laser comprises a dual output laser having first and second output ports of said active waveguide on opposite first and second sides of said semiconductor waveguide laser that each output laser light.

Example 56. The waveguide-based optical device of Example 55, wherein said waveguide portion of said SOA1 is optically coupled to receive laser light from said first output port of said dual output laser.

Example 57. The waveguide-based optical device of Example 56, wherein said waveguide portion of said isolation section is optically coupled to receive laser light from said first output port of said dual output laser and to transmit said laser light to said waveguide portion of said SOA1.

Example 58. The waveguide-based optical device of any of the Examples above, wherein a waveguide portion of a third semiconductor optical amplifier (SOA3) is optically coupled to receive laser light from said second output port of said dual output laser.

Example 59. The waveguide-based optical device of any of the Examples above, further comprising an additional isolation section having a waveguide portion that is optically coupled to receive laser light from said second output port of said dual output laser and transmit said laser light to said waveguide portion of said SOA3.

Example 60. The waveguide-based optical device of any of the Examples above, wherein said waveguide portion of said isolation section comprises has a constant cross section size and shape.

Example 61. The waveguide-based optical device of any of the Examples above, wherein said waveguide portion of said isolation section comprises has a constant index of refraction along the length thereof.

Example 62. The waveguide-based optical device of any of the Examples above, wherein optical absorption or amplification of the laser light, generated by the laser region, in the SOA1 is modulated by a periodic waveform comprising a plurality of modulation periods.

Example 63. The waveguide-based optical device of Example 62, wherein the modulation period is longer than 100 nanoseconds.

Example 64. The waveguide-based optical device of Example 62, wherein at least one of the optical attenuation, absorption and amplification of the laser light output from the SOA1 change by at least 5% during a modulation period.

Example 65. The waveguide-based optical device of Example 62, wherein the optical absorption and amplification of the laser light output from the SOA1 changes by at least 5% during a modulation period.

Example 66. The waveguide-based optical device of any of the Examples 1-61, wherein a voltage or a current applied to the SOA1 is modulated by a periodic waveform comprising a plurality of modulation periods.

Example 67. The waveguide-based optical device of Example 66, wherein the modulation period is longer than 100 nanoseconds.

Example 68. The waveguide-based optical device of Example 66, wherein the voltage or current applied to the SOA1 is configured to reverse bias and forward bias the SOA1 during a modulation period.

Example 69. The waveguide-based optical device of Example 66, wherein the amplitude of the voltage or current applied to the SOA1 changes by at least 5% of its peak value during a modulation period.

Example 70. The waveguide-based optical device of any of the Examples above, wherein amplification of the laser light, generated by the laser region, in the SOA1 is modulated by a periodic waveform comprising a plurality of modulation periods.

Example 71. The waveguide-based optical device of Example 70, wherein said periodic waveform comprises a modulated current and the SOA1 is forward biased during a modulation period.

Example 72. The waveguide-based optical device of any of the Examples 1-61, wherein absorption of the laser light, generated by the laser region, in the SOA1 is modulated by a periodic waveform comprising a plurality of modulation periods.

Example 73. The waveguide-based optical device of Example 72, wherein periodic waveform comprises a modulated voltage and the SOA1 is reverse biased during a modulation period.

Example 74. The waveguide-based optical device of any of the Examples 1-61, wherein absorption and the amplification of the laser light, generated by the laser region, in the SOA1 are modulated by a modulation signal having at least one modulation cycle.

Example 75. The waveguide-based optical device of Example 74, wherein the modulation signal is configured such that the SOA1 is reverse biased during a first portion of the modulation cycle, and forward biased during a second portion of the modulation cycle.

Example 76. The waveguide-based optical device of any of the Examples above, wherein the isolation section does not alter a polarization of light transmitted therethrough.

Example 77. The waveguide-based optical device of Example 76, wherein the isolation section does not alter a spectrum of light transmitted therethrough.

Example 78. The waveguide-based optical device of Example 77, wherein the isolation section does not comprise a grating.

Example 79. The waveguide-based optical device of any of the Examples above, wherein the isolation section does not comprise a beam splitter.

Example 80. The waveguide-based optical device of any of the Examples above, wherein the isolation section does not comprise a multiplexer or coupler.

Example 81. The waveguide-based optical device of any of the Examples above, wherein the isolation section does not comprise a mode converter.

Example 82. The waveguide-based optical device of any of the Examples above, wherein the isolation section attenuates light transmitted therethrough by less than 2%.

Example 83. The waveguide-based optical device of any of the Examples above, wherein at least one of optical attenuation, absorption or amplification of the laser light, generated by the laser region, in the SOA1 is modulated by an aperiodic waveform.

Example 84. The waveguide-based optical device of Example 83, wherein the optical attenuation, absorption or amplification of the laser light output from the SOA1 changes by at least 5%.

Example 85. The waveguide-based optical device of any of the Examples 83, wherein the amplitude of a voltage or current applied to the SOA1 changes by at least 5% of its peak value.

Example 86. The waveguide-based optical device of any of the Examples 83-85, wherein the aperiodic waveform is configured to forward bias the SOA1.

Example 87. The waveguide-based optical device of any of the Examples 83-85, wherein the aperiodic waveform is configured to reverse bias the SOA1.

Example 88. The waveguide-based optical device of any of the Examples 83-85, wherein the aperiodic waveform is configured to forward bias and reverse bias the SOA1.

Example 89. The waveguide-based optical device of Example 88, wherein the aperiodic waveform is configured to forward bias the SOA1 during an ON state and reverse bias the SOA during an OFF state.

Example 90. The waveguide-based optical device of any of the Examples above, wherein at least one of optical attenuation, absorption or amplification of the laser light, generated by the laser region, in the SOA1 is modulated or switched by a periodic waveform.

Group-6: Optical System with Isolation Section

Example 1. An optical system configured to generate a modulated or switched optical signal, the optical system comprising:
a waveguide-based optical device, the waveguide-based optical device extending in a longitudinal direction from a first end to a second end, said waveguide-based optical device comprising:
   a semiconductor chip comprising a semiconductor substrate;
   a laser region comprising a semiconductor waveguide laser on said semiconductor substrate, said semiconductor chip including said laser region, said laser region comprising an active waveguide portion configured to generate laser light;
   an integrated optical element comprising a shutter, attenuator, modulator, amplifier or absorber, said integrated optical element including a waveguide portion for receiving and propagating of laser light from said laser, said integrated optical element closer to said second end and said laser region closer to said first end; and
   an isolation section comprising a waveguide portion configured to transmit the laser light from the laser region to said integrated optical element, said isolation section between said laser region and said integrated optical element and configured to reduce heat transfer from said integrated optical element to said laser section, said isolation section having a length extending in the longitudinal direction, said isolation section not providing optical gain; and
an electronic circuit configured to provide a time varying electrical signal to the integrated optical element to modulate or switch the laser light received from the laser section;
wherein the length of the isolation section is at least 50% of the thickness of the semiconductor chip.

Example 2. The optical system of Example 1, wherein the waveguide portion of said isolation section comprises a material having a bandgap different from that of the active waveguide portion of said laser region.

Example 3. The optical system of Example 1 or 2, wherein the waveguide portion of the isolation section comprises a material having a bandgap different from the waveguide portion of said integrated optical element region.

Example 4. The optical system of any of the Examples above, wherein said isolation section is not configured to receive electrical power or an electrical signal.

Example 5. The optical system of any of the Examples above, wherein a length the isolation section is larger than 50% of the thickness of the active waveguide portion.

Example 6. The optical system of any of the Examples above, wherein the length of the isolation section is at least as large as 50% of the combined thickness of a top cladding layer, a core layer, and a bottom cladding layer of the waveguide laser.

Example 7. The optical system of any of the Examples above, wherein the length of the isolation section is greater than 50% of the thickness of the semiconductor chip.

Example 8. The optical system of any of the Examples above, wherein the length of the isolation section is greater than 50% of a thickness between the top of the active waveguide portion of said laser region to the bottom of the semiconductor chip.

Example 9. The optical system of any of the Examples above, wherein the length of the isolation section is larger than 50% of the thickness between the active waveguide portion of the laser region to the bottom of a substrate on which the waveguide laser is fabricated.

Example 10. The optical system of any of the Examples above, wherein the length of the isolation section is larger than 50% of the combined thickness of the active waveguide portion of the laser region, and any intervening layer between the active waveguide portion of the laser region and a chip carrier on which the semiconductor chip is mounted.

Example 11. The optical system of any of the Examples above, wherein the length of the isolation section is larger than 50% of a thickness of the semiconductor chip and any intervening layer between the semiconductor chip and a chip carrier on which the semiconductor chip is mounted.

Example 12. The optical system of any of the Examples above, wherein the length of the isolation section is larger than the thickness of the active waveguide portion or the laser region.

Example 13. The optical system of any of the Examples above, wherein the length of the isolation section is at least as large as a combined thickness of a top cladding layer, a core layer, and a bottom cladding layer of the waveguide laser.

Example 14. The optical system of any of the Examples above, wherein the length of the isolation section is greater than the thickness of the semiconductor chip.

Example 15. The optical system of any of the Examples above, wherein the length of the isolation section is greater than the thickness between the top of the active waveguide portion of the laser region to the bottom of the semiconductor chip.

Example 16. The optical system of any of the Examples above, wherein the length of the isolation section is larger than the thickness between the active region of the laser region to the bottom of a substrate on which the waveguide laser is fabricated.

Example 17. The optical system of any of the Examples above, wherein the length of the isolation section is larger than the combined thickness of the active waveguide portion of the laser region and any intervening layer between the active waveguide portion of the laser region and a chip carrier on which the semiconductor chip is mounted.

Example 18. The optical system of any of the Examples above, wherein the length of the isolation section is larger than the thickness of the semiconductor chip, and any intervening layer between the semiconductor chip and a chip carrier on which the semiconductor chip is mounted.

Example 19. The optical system of any of the Examples above, wherein said isolation section does not include an electrode configured to apply electrical voltage across said isolation section.

Example 20. The optical system of any of the Examples above, wherein said semiconductor chip includes one or more layers on said semiconductor substrate.

Example 21. The optical system of the Examples above, wherein said semiconductor chip includes one or more semiconductor layers on said semiconductor substrate.

Example 22. The optical system of the Examples above, wherein said laser region includes a plurality of reflectors forming a laser cavity.

Example 23. The optical system of Example 22, wherein at least one of said reflectors comprises a distributed Bragg reflector or a sampled Bragg grating reflector (SG-DBR).

Example 24. The optical system of any of the Examples 1-21, wherein said laser section comprises a distributed feedback (DFB) laser.

Example 25. The optical system of any of the Examples above, wherein said laser region includes one or more electrodes such that electrical power can be applied to at least part of said active waveguide portion of said laser region.

Example 26. The optical system of any of the Examples above, wherein the active waveguide of said laser region comprises III-V semiconductor material.

Example 27. The optical system of any of the Examples above, wherein said integrated optical element includes one or more electrodes configured such that electrical power can be applied to at least part of said waveguide portion of said integrated optical element.

Example 28. The optical system of Example 27, wherein said one or more electrodes are electrically connected to the electronic circuit to receive the time varying electrical signal.

Example 29. The optical system of any of the Examples above, wherein said integrated optical element comprises a shutter or modulator.

Example 30. The optical system of any of Example 1-28, wherein said integrated optical element comprises an attenuator.

Example 31. The optical system of any of Example 1-28, wherein said integrated optical element generates heat with application of electricity thereto.

Example 32. The optical system of any of the Examples above, wherein the active waveguide portion of said laser region and the active waveguide portion of said integrated optical element are monolithically fabricated on said semiconductor chip.

Example 33. The optical system of any of the Examples above, further comprising a semiconductor optical amplifier disposed between said laser region and said isolation section, said semiconductor optical amplifier comprising a waveguide portion having optical gain that is configured to propagate laser light from said laser region to said isolation section.

Example 34. The optical system of any of Example 33, wherein said semiconductor optical amplifier comprises at least one electrode configured such that to provide electrical power to said semiconductor optical amplifier.

Example 35. The optical system of any of the Examples 33 or 34, further comprising an additional isolation section between said laser region and said semiconductor optical amplifier, said additional isolation section comprising a waveguide portion configured to transmit laser light from the active waveguide portion of said laser region to said waveguide portion of semiconductor optical amplifier, said isolation section configured to reduce transfer of heat from said semiconductor optical amplifier to the laser section.

Example 36. The optical system of Example 35, wherein said additional isolation section is not configured to provide optical gain.

Example 37. The optical system of any of the Examples 35 or 36, wherein said waveguide portion of said additional isolation section has a length extending in the longitudinal direction that is at least 50% of the thickness of the semiconductor chip.

Example 38. The optical system of any of the Examples 35-37, wherein the length of the waveguide portion of the additional isolation section is larger than 50% of the thickness of the active waveguide portion.

Example 39. The optical system of any of the Examples 35-38, wherein the length of the waveguide portion of the additional isolation section is at least as large as 50% of the combined thickness of a top cladding layer, a core layer, and a bottom cladding layer of the waveguide laser.

Example 40. The optical system of any of the Examples 35-39, wherein the length of the waveguide portion of the additional isolation section is greater than 50% of the thickness of the semiconductor chip.

Example 41. The optical system of any of the Examples 35-40, wherein the length of the waveguide portion of the additional isolation section is greater than 50% of a thickness between the top of the active waveguide portion of said laser region to the bottom of the semiconductor chip.

Example 42. The optical system of any of the Examples 35-41, wherein the length of the waveguide portion of the additional isolation section is larger than 50% of the thickness between the active waveguide portion of the laser region to the bottom of a substrate on which the waveguide laser is fabricated.

Example 43. The optical system of any of the Examples 35-42, wherein the length of the waveguide portion of the additional isolation section is larger than 50% of the combined thickness of the active waveguide portion of the laser region, and any intervening layer between the active waveguide portion of the laser region and a chip carrier on which the semiconductor chip is mounted.

Example 44. The optical system of any of the Examples 35-43, wherein the length of the waveguide portion of the additional isolation section is larger than 50% of a thickness of the semiconductor chip and any intervening layer between the semiconductor chip and a chip carrier on which the semiconductor chip is mounted.

Example 45. The optical system of any of Example 35 or 36, wherein the length of the waveguide portion of the additional isolation section is larger than 50% of a thickness of a chip carrier or heat sink.

Example 46. The optical system of any the Examples above, wherein said isolation section is not configured to receive electrical power that produces heat.

Example 47. The optical system of any the Examples above, wherein said waveguide portion of said isolation section is not configured to receive electrical power that produces heat.

Example 48. The optical system of any the Examples above, wherein said semiconductor waveguide laser is formed on a semiconductor substrate and said semiconductor substrate is between said semiconductor waveguide laser and a chip carrier or heat sink.

Example 49. The optical system of Example 48, wherein said semiconductor substrate is bonded to said chip carrier or heat sink.

Example 50. The optical system of any the Examples above, wherein said semiconductor waveguide laser is formed on a semiconductor substrate and said semiconductor waveguide laser is between said semiconductor substrate and a chip carrier or heat sink.

Example 51. The optical system of Example 50, wherein said semiconductor substrate has layers formed thereon and at least one of said layers is bonded to said carrier or heat sink.

Example 52. The optical system of any of the Examples 48-51, wherein said semiconductor waveguide laser comprises semiconductor layers epitaxially grown on said semiconductor substrate.

Example 53. The optical system of any the Examples above, wherein said chip carrier or heat sink comprises metal.

Example 54. The optical system of any of Example 48, wherein the length of the waveguide portion of the isolation section is larger than 50% of a thickness of the chip carrier or heat sink.

Example 55. The optical system of any of the Examples above, wherein said semiconductor waveguide laser comprises a dual output laser having first and second output ports of said active waveguide on opposite first and second sides of said semiconductor waveguide laser that each output laser light.

Example 56. The optical system of Example 55, wherein said waveguide portion of said integrated optical element is optically coupled to receive laser light from said first output port of said dual output laser.

Example 57. The optical system of Example 56, wherein said waveguide portion of said isolation section is optically coupled to receive laser light from said first output port of said dual output laser and to transmit said laser light to said waveguide portion of said integrated optical element.

Example 58. The optical system of any of the Examples above, wherein a waveguide portion of an additional integrated optical element is optically coupled to receive laser light from said second output port of said dual output laser.

Example 59. The optical system of any of the Examples above, further comprising an additional isolation section having a waveguide portion that is optically coupled to receive laser light from said second output port of said dual output laser and transmit said laser light to said waveguide portion of said additional integrated optical element.

Example 60. The optical system of any of the Examples above, wherein said waveguide portion of said isolation section comprises has a constant cross section size and shape.

Example 61. The optical system of any of the Examples above, wherein said waveguide portion of said isolation section comprises has a constant index of refraction along the length thereof.

Example 62. The optical system of any of the Examples above, wherein the time varying signal is periodic waveform comprising a plurality of modulation periods, and wherein optical absorption or amplification of the laser light, generated by the laser region, in the integrated optical element is modulated by the periodic waveform.

Example 63. The optical system of Example 62, wherein the modulation period is longer than 100 nanoseconds.

Example 64. The optical system of Example 62, wherein the optical absorption or amplification of the laser light output from the integrated optical element changes by at least 5% during a modulation period.

Example 65. The optical system of any of the Examples 1-61, wherein the time varying signal comprises a periodic waveform, and wherein a voltage or a current applied to the integrated optical element by the electronic circuit is modulated by the periodic waveform comprising a plurality of modulation periods.

Example 66. The optical system of Example 65, wherein the modulation period is longer than 100 nanoseconds.

Example 67. The optical system of Example 65, wherein the amplitude of the voltage or current applied to the integrated optical element changes by at least 5% of its peak value during a modulation period.

Example 68. The optical system of any of the Examples above, wherein the electronic circuit modulates amplification of the laser light, generated by the laser region, in the integrated optical element by the time varying signal.

Example 69. The optical system of Example 68, wherein the time varying signal comprises a modulated current and the integrated optical element is forward biased during a modulation period.

Example 70. The optical system of any of the Examples 1-61, wherein the electronic circuit modulates absorption of the laser light, generated by the laser region, in the integrated optical element by the time varying signal.

Example 71. The optical system of Example 70, wherein the time varying signal comprises a modulated voltage and the integrated optical element is reverse biased during a modulation period.

Example 72. The optical system of any of the Examples 1-61, wherein the electronic circuit modulates absorption and the amplification of the laser light, generated by the laser region, in the integrated optical element by a time varying signal.

Example 73. The optical system of Example 72, wherein the time varying signal comprises a modulated voltage during a first portion of a modulation period and comprises a modulated current during a second portion of the modulation period, the integrated optical element is reverse biased during the first portion of the modulation period, and forward biased during the second portion of the modulation period.

Example 74. The optical system of any of the Examples above, wherein the time varying signal comprises a periodic waveform having a plurality of substantially equal modulation periods.

Example 75. The optical system of any of the Examples above, wherein the time varying signal comprises an aperiodic waveform having a plurality of modulation periods, one or both temporal length and a waveform portion of at least two modulation periods being different.

Example 76. The optical system of any of the Examples above, wherein the isolation section does not alter a polarization of light transmitted therethrough.

Example 77. The optical system of Example 76, wherein the isolation section does not alter a spectrum of light transmitted therethrough.

Example 78. The optical system of Example 77, wherein the isolation section does not comprise a grating.

Example 79. The optical system of any of the Examples above, wherein the isolation section does not comprise a beam splitter.

Example 80. The optical system of any of the Examples above, wherein the isolation section does not comprise a multiplexer or coupler.

Example 81. The optical system of any of the Examples above, wherein the isolation section does not comprise a mode converter.

Example 82. The optical system of any of the Examples above, wherein the isolation section attenuates light transmitted therethrough by less than 2%.

Example 83. The waveguide-based optical device of any of the Examples above, wherein the time varying signal comprises an aperiodic waveform, wherein at least one of optical attenuation, absorption, or amplification of the laser light, generated by the laser region, in the integrated optical element is modulated by the aperiodic waveform.

Example 84. The optical system of Example 83, wherein the optical attenuation, absorption or amplification of the laser light output from the integrated optical element changes by at least 5%.

Example 85. The optical system of Example 83, wherein the amplitude of a voltage or current applied to the integrated optical element changes by at least 5% of its peak value.

Example 86. The optical system of any of the Examples 83-85, wherein the aperiodic waveform is configured to forward bias the integrated optical element.

Example 87. The optical system of any of the Examples 83-85, wherein the aperiodic waveform is configured to reverse bias the integrated optical element.

Example 88. The optical system of any of the Examples 83-85, wherein the aperiodic waveform is configured to forward bias and reverse bias the integrated optical element.

Example 89. The optical system of Example 88, wherein the aperiodic waveform is configured to forward bias the integrated optical element during an ON state and reverse bias the SOA during an OFF state.

Example 90. The optical system of any of the Examples above, wherein the electronic circuit comprises a four-quadrant electrical supply.

Example 91. The optical system any of the Examples above, wherein the electronic circuit is fabricated on the semiconductor substrate.

Example 92. The optical system any of the Examples above, wherein the electronic circuit is fabricated on the semiconductor chip.

Example 93. The optical system any of the Examples above, wherein integrated optical element comprises a semiconductor optical amplifier (SOA).

Example 94. The optical system of any of the Examples above, wherein the time varying signal comprises a periodic waveform, and wherein at least one of optical attenuation, absorption, or amplification of the laser light, generated by the laser region, in the integrated optical element is modulated or switched by the periodic waveform.

Group-7: Optical System without Isolation Section

Example 1. An optical system configured to generate a modulated or switched optical signal, the optical system comprising:
a waveguide-based optical device, the waveguide-based optical device extending in a longitudinal direction from a first end to a second end, said waveguide-based optical device comprising:
   a semiconductor chip comprising a semiconductor substrate;
   a laser region comprising a semiconductor waveguide laser on said semiconductor substrate, said semiconductor chip including said laser region, said laser region comprising an active waveguide portion configured to generate laser light;
   a first semiconductor optical amplifier (SOA1) configured to modulate or switch laser light received from the laser section, said SOA1 including a waveguide portion for receiving and propagating of laser light from said laser, said SOA1 closer to said second end and said laser region closer to said first end; and
   a second semiconductor optical amplifier (SOA2) configured to amplify laser light received from the laser section, said SOA2 comprising a waveguide portion configured to transmit from the laser region to said SOA1, said SOA2 between said laser region and said SOA1 thereby reducing heat transfer from said SOA1 to said laser section; and
   an electronic circuit configured to provide a time varying signal to the SOA1 to modulate or switch laser light received from the laser section.

Example 2. The optical system of Example 1, wherein said semiconductor chip includes one or more layers on said semiconductor substrate.

Example 3. The optical system of the Examples above, wherein said semiconductor chip includes one or more semiconductor layers on said semiconductor substrate.

Example 4. The optical system of the Examples above, wherein said laser region includes a plurality of reflectors forming a laser cavity.

Example 5. The optical system of Example 4, wherein at least one of said reflectors comprises a distributed Bragg reflector or a sampled Bragg grating reflector (SG-DBR).

Example 6. The optical system of any of the Examples 1-5, wherein said laser section comprises a distributed feedback (DFB) laser.

Example 7. The optical system of any of the Examples above, wherein said laser region includes one or more electrodes such that electrical power can be applied to at least part of said active waveguide portion of said laser region.

Example 8. The optical system of any of the Examples above, wherein the active waveguide portion of said laser region comprises III-V semiconductor material.

Example 9. The optical system of any of the Examples above, wherein said SOA1 includes one or more electrodes configured such that electrical power can be applied to at least part of said waveguide portion of said SOA1.

Example 10. The optical system of Example 9, wherein said one or more electrodes are electrically connected to the electronic circuit to receive the time varying electrical signal.

Example 11. The optical system of any of the Examples above, wherein SOA1 generate heat with application of the time varying signal.

Example 12. The optical system of any the Examples above, wherein said semiconductor waveguide laser is formed on the semiconductor substrate and said semiconductor substrate is between said semiconductor waveguide laser and a chip carrier or heat sink.

Example 13. The optical system of Example 12, wherein said semiconductor substrate is bonded to said chip carrier or heat sink.

Example 14. The optical system of Example 1, wherein said semiconductor substrate has layers formed thereon and at least one of said layers is bonded to said carrier or heat sink.

Example 15. The optical system of any of the Examples above, wherein said semiconductor waveguide laser comprises semiconductor layers epitaxially grown on said semiconductor substrate.

Example 16. The optical system of any the Examples above, wherein said chip carrier or heat sink comprises metal.

Example 17. The optical system of any of the Examples above, wherein the active waveguide portion of said laser region and the active waveguide portion of said SOA1 are monolithically fabricated on said semiconductor chip.

Example 18. The optical system of Example 17, wherein said SOA1 and said SOA2 comprise semiconductor layers epitaxially grown on said semiconductor substrate.

Example 19. The optical system of Example 18, wherein the active waveguide portion of said laser region and an active waveguide portion of said SOA1 comprise at least one common layer.

Example 20. The optical system of Example 18, wherein the active waveguide portion of said laser region and an active waveguide portion of said SOA2 comprise at least one common layer.

Example 21. The optical system of Example 18, wherein an active waveguide portion of said SOA1 and an active waveguide portion of said SOA2 comprise at least one common layer.

Example 22. The optical system of Example 1, wherein said SOA1 comprises at least one electrode configured to provide electrical power to said SOA1.

Example 23. The optical system of any of the Examples above, wherein said SOA2 comprises at least one electrode configured to provide electrical power to said SOA2.

Example 24. The optical system of any of the Examples above, wherein said semiconductor waveguide laser comprises a dual output laser having first and second output ports of said active waveguide on opposite first and second sides of said semiconductor waveguide laser that each output laser light.

Example 25. The optical system of Example 24, wherein said waveguide portion of said SOA1 is optically coupled to receive laser light from said first output port of said dual output laser.

Example 26. The optical system of any of the Examples above, wherein a waveguide portion of a third semiconductor optical amplifier (SOA3) is optically coupled to receive laser light from said second output port of said dual output laser.

Example 27. The optical system of any of the Examples above, wherein the time varying signal comprises a periodic waveform having a plurality of substantially equal modulation periods.

Example 28. The optical system of any of the Examples above, wherein the time varying signal comprises an aperiodic waveform having a plurality of modulation periods, one or both temporal length and a waveform portion of at least two modulation periods are different.

Example 29. The optical system of any of the Examples above, wherein the time varying signal modulates optical absorption or amplification of the laser light, generated by the laser region during a modulation period.

Example 30. The optical system of Example 29, wherein the modulation period is longer than 100 nanoseconds.

Example 31. The optical system of Example 29, wherein the time varying signal varies the optical absorption or amplification of the laser light output from the SOA1 by at least 5% during a modulation period of the plurality of modulation periods.

Example 32. The optical system of any of the Examples above, wherein the time varying signal comprises a voltage or a current applied to the SOA1.

Example 33. The optical system of Example 32, wherein the amplitude of the voltage or current applied to the SOA1 changes by at least 5% of its peak value during a modulation period.

Example 34. The optical system of any of the Examples above, wherein the electronic circuit modulates amplification of the laser light, generated by the laser region, in the SOA1 by the time varying signal.

Example 35. The optical system of Example 34, wherein the time varying signal comprises a modulated current and the SOA1 is forward biased during a modulation period.

Example 36. The optical system of any of the Examples 1-33, wherein the electronic circuit modulates absorption of the laser light, generated by the laser region, in the SOA1 by the time varying signal.

Example 37. The optical system of Example 36, wherein the time varying signal comprises a modulated voltage and the SOA1 is reverse biased during a modulation period.

Example 38. The optical system of any of the Examples 1-33, wherein the electronic circuit modulates absorption and the amplification of the laser light, generated by the laser region, in the SOA1 by the time varying signal.

Example 39. The optical system of Example 38, wherein the time varying signal comprises a modulated voltage during a first portion of a modulation period and comprises a modulated current during a second portion of the modulation period, the SOA1 is reverse biased during the first portion of the modulation period, and forward biased during the second portion of the modulation period.

Example 40. The optical system of any of the Examples above, wherein the electronic circuit comprises a four-quadrant electrical supply.

Example 41. The optical system of any of any of the Examples above, wherein the time varying signal comprises an a period waveform, wherein at least one of optical attenuation, absorption or amplification of the laser light, generated by the laser region, in the SOA1 is modulated by the aperiodic waveform.

Example 42. The optical system of Example 39, wherein the optical attenuation, absorption or amplification of the laser light output from the SOA1 changes by at least 5%.

Example 43. The optical system of Examples 39, wherein the amplitude of a voltage or current applied to the SOA1 changes by at least 5% of its peak value.

Example 44. The optical system of any of the Examples 39-40, wherein the aperiodic waveform is configured to forward bias the SOA1.

Example 45. The optical system of any of the Examples 39-40, wherein the aperiodic waveform is configured to reverse bias the SOA1.

Example 46. The optical system of any of the Examples 39-40, wherein the aperiodic waveform is configured to forward bias and reverse bias the SOA1.

Example 47. The optical system of Example 44, wherein the aperiodic waveform is configured to forward bias the SOA1 during an ON state and reverse bias the SOA1 during an OFF state.

Example 48. The optical system of any of the Examples above, wherein the electronic circuit is fabricated on the semiconductor substrate.

Example 49. The optical system of any of the Examples above, wherein the electronic circuit is fabricated on the semiconductor chip.

Example 50. The optical system of any of the Examples above, wherein the time varying signal comprises a periodic waveform, and wherein at least one of optical attenuation, absorption, or amplification of the laser light, generated by the laser region, in the SOA1 is modulated or switched by the periodic waveform.

### Terminology

Conditional language, such as “can,” “could,” “might,” or “may” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments.

Conjunctive language such as the phrase “at least one of X, Y, and Z,” unless specifically stated otherwise, is to be understood within the context used in general to convey that an item, term, etc. may be either X, Y, or Z. Thus, such conjunctive language is not generally intended to imply that certain embodiments require the presence of at least one of X, at least one of Y, and at least one of Z.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by ±5 degrees, by ±2 degrees, by ±1 degree, or by ±0.1 degree, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree.

Various configurations have been described above. Although this invention has been described with reference to these specific configurations, the descriptions are intended to be illustrative of the invention and are not intended to be limiting. Various modifications and applications may occur to those skilled in the art without departing from the true spirit and scope of the invention. Thus, for example, in any method or process disclosed herein, the acts or operations making up the method/process may be performed in any suitable sequence and are not necessarily limited to any particular disclosed sequence. Features or elements from various embodiments and examples discussed above may be combined with one another to produce alternative configurations compatible with embodiments disclosed herein. Various aspects and advantages of the embodiments have been described where appropriate. It is to be understood that not necessarily all such aspects or advantages may be achieved in accordance with any particular embodiment. Thus, for example, it should be recognized that the various embodiments may be carried out in a manner that achieves or optimizes one advantage or group of advantages as taught herein without necessarily achieving other aspects or advantages as may be taught or suggested herein.

What is claimed is:

1. A waveguide-based optical device extending in a longitudinal direction from a first end to a second end, said waveguide-based optical device comprising:
a semiconductor chip comprising a semiconductor substrate;
a laser region comprising a semiconductor waveguide laser on said semiconductor substrate, said semiconductor chip including said laser region, said laser region comprising an active waveguide portion configured to generate laser light;
an integrated optical element comprising a shutter, attenuator, modulator, amplifier or absorber, said integrated optical element including a waveguide portion for propagation of laser light from said laser, said integrated optical element closer to said second end and said laser region closer to said first end; and
an isolation section comprising a waveguide portion configured to transmit the laser light from the laser region to said integrated optical element, said isolation section between said laser region and said integrated optical element and configured to reduce heat transfer from said integrated optical element to said laser region, said isolation section having a length extending in the longitudinal direction, said isolation section not providing optical gain;
wherein the length of the isolation section is at least 50% of the thickness of the semiconductor chip.

2. The waveguide-based optical device of claim 1, wherein the waveguide portion of said isolation section comprises a material having a bandgap different from that of the active waveguide portion of said laser region.

3. The waveguide-based optical device of claim 1, wherein the waveguide portion of the isolation section comprises a material having a bandgap different from the waveguide portion of said integrated optical element region.

4. The waveguide-based optical device of claim 1, wherein the length of the isolation section is greater than 50% of the thickness of the semiconductor chip.

5. The waveguide-based optical device of claim 1, wherein the length of the isolation section is greater than 50% of a thickness between the top of the active waveguide portion of said laser region to the bottom of the semiconductor chip.

6. The waveguide-based optical device of claim 1, wherein said isolation section does not include an electrode configured to apply electrical voltage across said isolation section.

7. The waveguide-based optical device of claim 1, the integrated optical element is configured to modulate or switch laser light received from the laser region.

8. The waveguide-based optical device of claim 1, wherein said laser region comprises a distributed Bragg reflector or a sampled Bragg grating reflector (SG-DBR).

9. The waveguide-based optical device of claim 1, wherein said laser region comprises a distributed feedback (DFB) laser.

10. The waveguide-based optical device of claim 1, wherein said integrated optical element includes one or more electrodes configured such that electrical power can be applied to at least part of said waveguide portion of said integrated optical element.

11. The waveguide-based optical device of claim 1, wherein said one or more electrodes are electrically connected to electronics configured to drive said one or more electrodes with a time varying electrical signal.

12. The waveguide-based optical device of claim 1, further comprising a semiconductor optical amplifier disposed between said laser region and said isolation section, said semiconductor optical amplifier comprising a waveguide portion having optical gain that is configured to propagate laser light from said laser region to said isolation section.

13. The waveguide-based optical device of claim 12, wherein said semiconductor optical amplifier comprises at least one electrode configured such that to provide electrical power to said semiconductor optical amplifier.

14. The waveguide-based optical device of claim 12, further comprising an additional isolation section between said laser region and said semiconductor optical amplifier, said additional isolation section comprising a waveguide portion configured to transmit laser light from the active waveguide portion of said laser region to said waveguide portion of semiconductor optical amplifier, said isolation section configured to reduce transfer of heat from said semiconductor optical amplifier to the laser region.

15. The waveguide-based optical device of claim 14, wherein said additional isolation section is not configured to provide optical gain.

16. The waveguide-based optical device of claim 1, wherein said semiconductor waveguide laser is formed on a semiconductor substrate and said semiconductor substrate is between said semiconductor waveguide laser and a chip carrier or heat sink.

17. The waveguide-based optical device of claim 16, wherein said semiconductor substrate is bonded to said chip carrier or heat sink.

18. The waveguide-based optical device of claim 17, wherein said semiconductor waveguide laser is formed on a semiconductor substrate and said semiconductor waveguide laser is between said semiconductor substrate and a chip carrier or heat sink.

19. The waveguide-based optical device of claim 18, wherein said semiconductor substrate has layers formed thereon and at least one of said layers is bonded to said chip carrier or heat sink.

20. The waveguide-based optical device of claim 16, wherein said semiconductor waveguide laser comprises semiconductor layers epitaxially grown on said semiconductor substrate.

21. The waveguide-based optical device of claim 16, wherein the length of the waveguide portion of the isolation section is larger than 50% of a thickness of the chip carrier or heat sink.

22. The waveguide-based optical device of claim 1, wherein said semiconductor waveguide laser comprises a dual output laser having first and second output ports of said active waveguide portion on opposite first and second sides of said semiconductor waveguide laser that each output laser light.

23. The waveguide-based optical device of claim 22, wherein said waveguide portion of said integrated optical element is optically coupled to receive laser light from said first output port of said dual output laser.

24. The waveguide-based optical device of claim 23, wherein said waveguide portion of said isolation section is optically coupled to receive laser light from said first output port of said dual output laser and to transmit said laser light to said waveguide portion of said integrated optical element.

25. The waveguide-based optical device of claim 24, further comprising a semiconductor optical amplifier disposed between said laser region and said isolation section, said semiconductor optical amplifier comprising a waveguide having optical gain, said waveguide configured to receive laser light from said first output port of said dual output laser and to propagate laser light from said first output port to said waveguide portion of said isolation section.

26. The waveguide-based optical device of claim 25, further comprising an additional isolation section dispose between said laser and said semiconductor optical amplifier, said additional isolation section comprising a waveguide portion configured to transmit laser light from the active waveguide portion of said laser region to said waveguide portion of semiconductor optical amplifier, said additional isolation section configured to reduce transfer of heat from said semiconductor optical amplifier to the laser region; wherein the length of the additional isolation section is at least 50% of the thickness of the semiconductor chip.

27. The waveguide-based optical device of claim 1, wherein at least one of absorption, attenuation, and amplification of the laser light, generated by the laser region, in the integrated optical element are modulated by a time varying signal comprising a waveform.

28. The waveguide-based optical device of claim 27, wherein the waveform comprises a periodic voltage or a current applied to the integrated optical element.

29. The waveguide-based optical device of claim 27, wherein the waveform comprises an aperiodic voltage or a current applied to the integrated optical element.

30. The waveguide-based optical device of claim 27, wherein the waveform is configured to reverse bias the integrated optical element during a first portion of a modulation period, and forward bias the integrated optical element during a second portion of the modulation period.
